(19) United States
(12) Patent Application Publication
(10) Pub. No.: US 2024/0322802 A1
(43) Pub. Date: Sep. 26, 2024

(54) DEVICE AND CIRCUIT FOR MEASURING A DERIVATIVE

(71) Applicant: STMicroelectronics (Grenoble) SAS, Grenoble (FR)

(72) Inventors: Jean Camiolo, Sassenage (FR); Geoffroy Godet, Grenoble (FR)

(21) Appl. No.: 18/583,474

(22) Filed: Feb. 21, 2024

(30) Foreign Application Priority Data
Mar. 24, 2023 (FR) 2302835

(51) Int. Cl. H03K 3/023; G01R 15/16

(52) U.S. Cl. CPC H03K 3/023; G01R 15/16

(57) ABSTRACT

The present description concerns a derivative measurement circuit. The circuit implements successive cycles, each corresponding to a succession of first, second, and third periods of a clock signal. At each first period, an input voltage is memorized on a first capacitive element and the circuit delivers a voltage indicating a difference between a voltage on a second capacitive element and a voltage on a third capacitive element. At each second period, the input voltage is memorized on the second capacitive element and the circuit delivers a voltage indicating a difference between a voltage on the first capacitive element and the voltage on the third capacitive element. At each third period, the input voltage is memorized on the third capacitive element and the circuit delivers a voltage indicating a difference between the voltage on the second capacitive element and the voltage on the first capacitive element.

### CROSS-REFERENCE TO RELATED APPLICATIONS

This application claims the priority benefit of French patent application number 23/02835, filed on Mar. 24, 2023, entitled “Derivative measurement circuit,” which is hereby incorporated herein by reference to the maximum extent allowable by law.

### TECHNICAL FIELD

The present disclosure generally concerns electronic circuits, for example integrated circuits, and, more particularly, a circuit for measuring a derivative and a device comprising such a measurement circuit.

### BACKGROUND

Many known applications and devices implement a measurement (or calculation) of a derivative, for example of the derivative of a voltage indicating a value of a physical quantity such as a current or a temperature.

To obtain a measurement of the derivative of a voltage, that is, a value of the derivative of the voltage, a solution consists of using an operational amplifier assembled as a voltage differentiator. However, this solution has various disadvantages. In particular, this solution is not adapted for wide frequency ranges of the input signal of the operational amplifier. Further, this solution requires an operational amplifier having a bandwidth greater than the frequency range of the input signal.

Another solution consists of using an analog-to-digital converter (ADC) to digitize the voltage on which the derivative will be calculated, and a microprocessor that reads the output of the ADC and calculates the derivative of the input voltage of the ADC. However, this solution is complex due to the fact that it requires an ADC and a microprocessor. Further, the conversion time of the ADC to which is added the computing time of the microprocessor may be too long, for example when countermeasures have to be implemented as soon as the derivative exceeds a threshold.

There exist still other known solutions to measure, that is, calculate, the derivative of a voltage, but these known solutions also suffer from disadvantages.

There thus exists a need to overcome all or part of the disadvantages of known derivative measurement circuits.

### SUMMARY

An embodiment overcomes all or part of the disadvantages of known derivative measurement circuits.

An embodiment provides a derivative measurement circuit comprising:
M capacitive elements, M being an integer greater than or equal to 1, each having a first terminal connected to a first input of the measurement circuit configured to receive a reference potential;
M first switches coupling a second terminal of each of the M elements to a first node configured to receive a first voltage determined by a voltage at a second input of the measurement circuit coupled with the first node;
a first circuit configured to deliver, at a first output of the measurement circuit, a second voltage indicating a value of a voltage difference between first and second inputs of the first circuit;
second switches coupling the second terminal of each of the M elements to the inputs of the first circuit; and
a control circuit configured to:
   receive a first clock signal available at a third input of the measurement circuit;
   implement successive cycles corresponding each to a succession of M periods of a second clock signal determined by the first clock signal; and
   control the switches in such a way that, at each period of each cycle:
the first voltage is memorized on one of the M capacitive elements; and
the first input of the first circuit receives a voltage memorized at a first instant on one of the M capacitive elements and the second input of the first circuit receives a voltage representative of the first voltage at a second instant different from the first instant.

According to an embodiment:
M is equal to 1;
the first input of the first circuit is coupled to the first node; and
the control circuit is configured to control the switches in such a way that, at each period of each cycle, the second input of the first circuit receives the voltage memorized on the capacitive element at this period.

According to an embodiment:
M is equal to 2; and
the control circuit is configured to control the switches in such a way that, at each cycle:
that of the M capacitive elements on which the first voltage is memorized is different at each period of the cycle, and
at each period of the cycle, the second input of the first circuit receives a voltage across the terminals of one of the M capacitive elements other than the one on which the memorization is done at this cycle, and the first input of the first circuit receives a voltage across the other of the M capacitive elements.

According to an embodiment:
M is equal to 3; and
the control circuit is configured to control the switches in such a way that, at each cycle:
that of the M capacitive elements on which the first voltage is memorized is different at each period of the cycle, and
at each period of the cycle, the first input of the first circuit receives a voltage across the terminals of one of the M capacitive elements other than the one on which the memorization is done at this period, and the second input of the first circuit receives a voltage across another of the M capacitive elements other than the one on which the memorization is done at this period.

According to an embodiment:
M is equal to 3;
each cycle corresponds to a succession of first, second and third periods of the second clock signal; and
the control circuit is configured to control the switches in such a way that:
at each first period, the first voltage is memorized on the first element and the first and second inputs of the first circuit receive voltages of the third and second elements respectively,
at each second period, the first voltage is memorized on the second element and the first and second inputs of the first circuit receive voltages of the first and third elements respectively, and
at each third period, the first voltage is memorized on the third element and the first and second inputs of the first circuit receive voltages of the second and first elements respectively.

According to an embodiment, the first switches comprise a first first switch coupling the second terminal of the first element with the first node, a second first switch coupling the second terminal of the second element with the first node, and a third first switch coupling the second terminal of the third element with the first node.

According to an embodiment, the control circuit is configured to:
at each first period, keep open the second and third first switches and switch the first first switch to the ON state;
at each second period, keep open the third and first first switches and switch the second first switch to the ON state; and
at each third period, keep open the second and first first switches and switch the third first switch to the ON state.

According to an embodiment, each memorization of the first voltage on a capacitive element has a same duration, for example less than or equal to one period of the second clock signal, preferably equal to half a period of the second clock signal.

According to an embodiment, the second switches comprise:
first and second second switches coupling the second terminal of the first element respectively with the first and second inputs of the first circuit;
third and fourth second switches coupling the second terminal of the second element respectively with the first and second inputs of the first circuit; and
fifth and sixth second switches coupling the second terminal of the third element respectively with the first and second inputs of the first circuit.

According to an embodiment, the control circuit is configured to:
at each first period, switch the fifth and fourth second switches to the ON state and keep open the other second switches;
at each second period, switch the first and sixth second switches to the ON state and keep open the other second switches; and
at each third period, switch the third and second second switches to the ON state and keep open the other second switches.

According to an embodiment, the measurement circuit comprises a smoothing capacitive element connected between the first input of the first circuit and the first input of the measurement circuit and a smoothing capacitive element connected between the second input of the first circuit and the first input of the measurement circuit.

According to an embodiment, the measurement circuit further comprises a second circuit coupling the second input of the measurement circuit with the first node, the second circuit being a buffer circuit.

According to an embodiment, the measurement circuit comprises:
a first comparator configured to compare the second voltage with a positive threshold voltage delivered by the control circuit, and to provide a first binary signal indicating if the second voltage is greater than the positive threshold voltage; and/or
a second comparator configured to compare the second voltage with a negative threshold voltage provided by the control circuit, and to provide a second binary signal indicating if the second voltage is lower than the negative threshold voltage.

According to an embodiment:
the measurement circuit comprises the first comparator; and
the control circuit is configured to adapt the value of the positive threshold voltage as a function of the value of the first voltage.

According to an embodiment, the control circuit is configured to decrease the value of the positive threshold voltage when the first voltage is positive and increases.

According to an embodiment:
the measurement circuit comprises the second comparator; and
the control circuit is configured to adapt the value of the negative threshold voltage as a function of the value of the first voltage.

According to an embodiment, the control circuit is configured to decrease the absolute value of the negative threshold voltage when the first voltage is negative and decreases.

Another embodiment provides a circuit for measuring a derivative comprising:
first, second, and third capacitive elements, each having a first terminal connected to a first input of the measurement circuit configured to receive a reference potential;
first switches coupling a second terminal of each of the elements to a first node configured to receive a first voltage determined by a second voltage on a second input of the measurement circuit having the first node coupled thereto;
a first circuit configured to deliver, at a first output of the measurement circuit, a third voltage indicating a value of a voltage difference between first and second inputs of the first circuit;
second switches coupling the second terminal of each of the elements to the inputs of the first circuit; and
a control circuit configured to:
   receive a first clock signal available on a third input of the measurement circuit;
   implement successive cycles, each corresponding to a succession of first, second, and third periods of a second clock signal determined by the first clock signal; and
   control the switches so that:
at each first period, the first voltage is memorized on the first element and the first and second inputs of the first circuit receive voltages from the third and second elements respectively,
at each second period, the first voltage is memorized on the second element and the first and second inputs of the first circuit receive voltages of the first and third elements respectively, and
at each third period, the first voltage is memorized on the third element and the first and second inputs of the first circuit receive voltages of the second and first elements respectively.

According to an embodiment, there is provided a device comprising an integrated circuit chip comprising the above measurement circuit, a controllable resistor external to the chip and having a control input configured to receive a control signal at least partly determined by the first output of the measurement circuit, and a second circuit connected to the controllable resistor and configured to deliver, to the second input of the measurement circuit, the second voltage indicating a value of the current in the controllable resistor, the second circuit for example forming part of the chip.

According to an embodiment, the first switches comprise a first first switch coupling the second terminal of the first element with the first node, a second first switch coupling the second terminal of the second element with the first node, and a third first switch coupling the second terminal of the third element with the first node.

According to an embodiment, the control circuit is configured to:
at each first period, keep open the second and third first switches and switch the first first switch to the ON state;
   at each second period, keep open the third and first first switches and switch the second first switch to the ON state; et
   at each third period, keep open the second and first first switches and switch the third first switch to the ON state.

According to an embodiment, each memorization of the first voltage on a capacitive element has a same duration, for example less than or equal to a period of the second clock signal, preferably equal to half a period of the second clock signal.

According to an embodiment, the same duration is the duration in the ON state of the first, second, and third first switches during each of the first, second, and third periods, respectively.

According to an embodiment, the second switches comprise:
first and second second switches coupling the second terminal of the first element respectively with the first and second inputs of the first circuit;
third and fourth second switches coupling the second terminal of the second element respectively with the first and second inputs of the first circuit; and
fifth and sixth second switches coupling the second terminal of the third element respectively with the first and second inputs of the first circuit.

According to an embodiment, the control circuit is configured to:
at each first period, switch the fifth and fourth second switches to the ON state and keep the other second switches open;
at each second period, switch the first and sixth second switches to the ON state and keep the other second switches open; and
at each third period, switch the third and second second switches to the ON state and keep the other second switches open.

According to an embodiment, the measurement circuit comprises a smoothing capacitive element connected between the first input of the first circuit and the first input of the measurement circuit and a smoothing capacitive element connected between the second input of the first circuit and the first input of the measurement circuit.

According to an embodiment, the measurement circuit further comprises a third circuit coupling the second input of the measurement circuit with the first node, the third circuit being a buffer circuit configured to receive the second voltage and deliver the first voltage.

According to an embodiment, the measurement circuit further comprises a fourth circuit coupled, preferably connected, with the first and second inputs of the first circuit, the fourth circuit being configured to deliver, at a second output of the measurement circuit, a signal indicating which of the voltages of the first and second inputs of the first circuit is higher than the other.

According to an embodiment, the measurement circuit further comprises a fifth circuit configured to compare the third voltage with a first threshold and to deliver, at a third output of the measurement circuit, a signal indicating a result of the comparison.

According to an embodiment:
the controllable resistor comprises a plurality of first resistors in series and switches controlled by the signal for controlling the controllable resistor and each configured to bypass a given number of the first resistors;
the second circuit is configured to compare, for each of the first resistors, a voltage across this first resistor with at least one corresponding threshold; and
the device further comprises a sixth circuit configured to deliver the control signal of the resistor based on the results of the comparisons and on the second output of the measurement circuit, the sixth circuit for example forming part of the chip.

According to an embodiment, the device comprises a processing circuit, for example a microprocessor, coupled to the first and third outputs of the measurement circuit and configured to receive the second voltage.

According to an embodiment, the device comprises a fourth capacitive element connected in parallel with the first capacitive element, a fifth capacitive element connected in parallel with the second capacitive element, a sixth capacitive element connected in parallel with the third capacitive element, the fourth, fifth, and sixth capacitive elements being external to the chip comprising the measurement circuit.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows, in the form of blocks, an example of a current measurement device;

FIG. 2 shows an example of embodiment of a derivative measurement circuit according to a first aspect;

FIG. 3 shows, in the form of blocks, an example of embodiment of a current measurement device comprising a derivative measurement circuit such as described in relation with FIG. 2;

FIG. 4 illustrates an example of embodiment of a derivative measurement circuit according to a second aspect;

FIG. 5 illustrates an example of embodiment of a derivative measurement circuit according to a third aspect;

FIG. 6 illustrates an example of embodiment of a derivative measurement circuit according to a fourth aspect;

FIG. 7 illustrates another example of embodiment of a derivative measurement circuit according to the fourth aspect;

FIG. 8 illustrates still another example of embodiment of a derivative measurement circuit according to the fourth aspect;

FIG. 9 illustrates still another example of embodiment of a measurement circuit according to the fourth aspect; and

FIG. 10 illustrates still another example of embodiment of a measurement circuit according to the fourth aspect.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, although the advantage of the embodiments and alternative embodiments of the derivative measurement circuit described herein is illustrated for a current measurement device, these embodiments and variants are compatibles with usual applications and devices where a derivative of a voltage is calculated, in particular, even when this voltage is not representative of a current but of another physical quantity, such as for example temperature.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

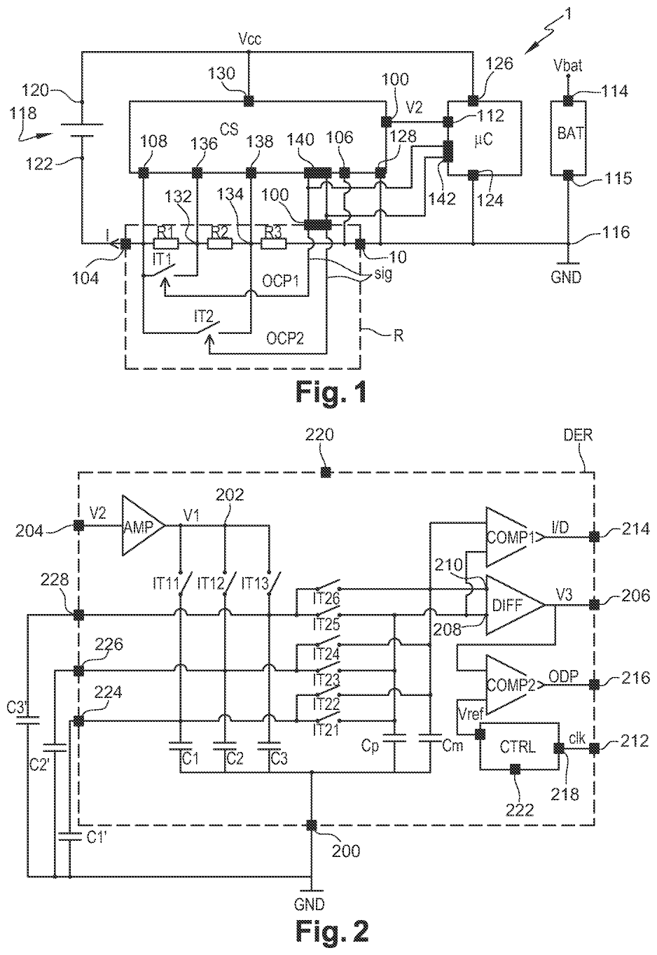

FIG. 1 shows, in the form of blocks, an example of a device 1 for measuring a current I.

Device 1 comprises a circuit CS and a controllable resistor R. Resistor R comprises an input 100 for receiving a control signal sig. Signal sig controls the value of resistor R. Resistor R comprises two terminals 102 and 104 connected to respective inputs 106 and 108 of circuit CS.

Circuit CS is configured to deliver a voltage V2, for example available on an output 110 of circuit CS, indicating the value of the current I flowing through resistor R.

As an example, device 1 comprises a processing circuit μC, for example a microcontroller, configured to receive voltage V2, for example on an input 112 of circuit μC.

As an example, device 1 further comprises a battery BAT having an upper terminal 114 configured to deliver a voltage Vbat, and a lower terminal 115 connected to a node 116 set to a reference potential GND, for example the ground.

As an example, device 1 further comprises a power source 118. Power source 118 has a high terminal 120 delivering a power supply voltage Vcc, and a low terminal 122.

As an example, resistor R is connected between node 116 and the low terminal 122 of voltage source 118.

As an example, circuit μC receives potential GND, for example on an input 124 of circuit μC connected to node 116. As an example, circuit μC receives voltage Vcc, for example on an input 126 of circuit μC.

As an example, circuit CS receives potential GND, for example on an input 128 of circuit CS connected to node 116. As an example, circuit CS receives voltage Vcc, for example on an input 130 of circuit CS.

Resistor R comprises N resistors Ri in series, with i an integer index ranging from 1 to N, and N an integer greater than or equal to 2, for example equal to three in FIG. 1 (R1, R2, and R3) between terminals 102 and 104 of resistor R. Resistors Ri are connected by order of increasing index i from one of terminals 102 and 104, for example terminal 104 in FIG. 1. For example, resistor R1 is connected between terminal 104 and a node 132, resistor R2 is connected between node 132 and a node 134, and resistor R3 is connected between node 134 and terminal 102.

Resistor R further comprises N−1 switches ITi, with i an integer index ranging from 1 to N−1. In the example of FIG. 1, resistor R thus comprises two switches IT1 and IT2. Each switch ITi is configured to bypass, when it is on, the resistors Ri of index i ranging from 1 to i. Thus, in the example of FIG. 1, switch IT1 is configured to bypass, when it is on, resistor R1, and switch IT2 is configured to bypass, when it is on, resistors R1 and R2.

Circuit CS is configured to compare, for each resistor Ri of resistor R, a voltage across this resistor Ri with at least one corresponding threshold.

For example, circuit CS comprises, in addition to its inputs 108 and 106 connected to respective terminals 104 and 102, and for each node 132, 134 of connection of two inner resistors R1 to R3 of resistor R, a corresponding input connected to this node. For example, circuit CS comprises an input 136 connected to node 132, and an input 138 connected to node 134.

Circuit CS is configured to adapt, or control, the value of controllable resistor R according to the value of the current I flowing therethrough. Indeed, when the current I through resistor R increases, for example during a transient current peak or overcurrent, if the value of resistor R is not modified, preferably decreased, the power dissipated in resistor R may reach values resulting in a destruction of resistor R. Circuit CS determines how to control each switch ITi of resistor R based on the comparisons of the voltages across each resistor Ri with at least one threshold corresponding to this resistor.

For example, when the voltage across a resistor Ri reaches or exceeds a first threshold that corresponds thereto, circuit CS controls the controllable resistor so that this resistor is bypassed, that is, controls the closing of the switch ITi associated with this resistor Ri, which enables to decrease the value of resistor R, and thus of the power that it dissipates.

For example, for each switch ITi, once switch ITi has been switched to the on state, this switch switches to the off state if the voltage across resistor Ri+1 decreases below a second threshold associated with this resistor.

Referring again to the example of FIG. 1, if current I increases and the voltage across resistor R1 exceeds the first threshold associated with this resistor R1, circuit CS controls the closing of switch IT1. If current I keeps on increasing and the voltage across resistor R2 exceeds the first threshold associated with this resistor R2, circuit CS controls the closing of switch IT2. If, while both switches IT1 and IT2 are on, current I decreases and the voltage across resistor R3 decreases below the second threshold associated with this resistor R3, circuit CS controls the opening of switch IT2. If current I keeps on decreasing and the voltage across resistor R2 decreases below the second threshold associated with this resistor R2, circuit CS controls the closing of switch IT1.

Thus, in the above example of operation, each resistor Ri, except for resistor R1 and for resistor RN, is associated with a first threshold to control the closing of the switch ITi that is associated thereto, and with a second threshold to control the closing of switch ITi−1. Resistor R1 is only associated with a first threshold to control the closing of the associated switch IT1, resistor RN only being associated with a second threshold to control the opening of switch RN−1.

Of course, other modes of control of resistor R to adapt its resistance value according to the current I that flows therethrough may be envisaged, just as the positioning of the switches enabling to bypass internal resistors of resistor R may be modified.

Circuit CS delivers a control signal sig to the control input 100 of resistor R, this signal sig being, for example, available on an output 140 of circuit CS. Signal sig is determined by the results of the comparisons of the voltages across the internal resistors R1 to R3 of resistor R with corresponding thresholds. Signal sig controls the switches IT1, IT2 of resistor R.

In this example, signal sig is formed of a signal OCP1 and of a signal OCP2. Signal OCP1 indicates whether the voltage across resistor R1 is greater or not than the threshold that corresponds thereto and controls switch IT1, signal OCP2 indicating whether the voltage across resistor R2 is greater or not than the threshold that corresponds thereto and controlling switch IT2.

As an example, circuit μC receives signal sig on an input 142 of circuit μC. For example, signal sig comprises signal OCP1 and signal OCP2.

Device 1 comprises a protection against overcurrents of current I. However, the comparisons of the voltages across the respective resistors R1 and R2 with corresponding thresholds are implemented by comparators having non-zero propagation times. As a result, during an increase of current I, the decrease of the value of resistor R may occur too late, that is, while current I has already reached values for which the power dissipated in resistor R is too high and results in a destruction of resistor R.

To avoid this, it would be desirable for device 1 to comprise a circuit for measuring the derivative of voltage V2, and thus the derivative of current I, and for a protection against overcurrents of current I to be implemented when this derivative reaches a threshold. In other words, it would be desirable to measure the derivative of voltage V2 to decrease the value of resistor R before the voltage across resistor R1 or the voltage across resistor R2 reaches its corresponding threshold when current I increases rapidly, that is, when the derivative of voltage V2 reaches a threshold.

### First Aspect

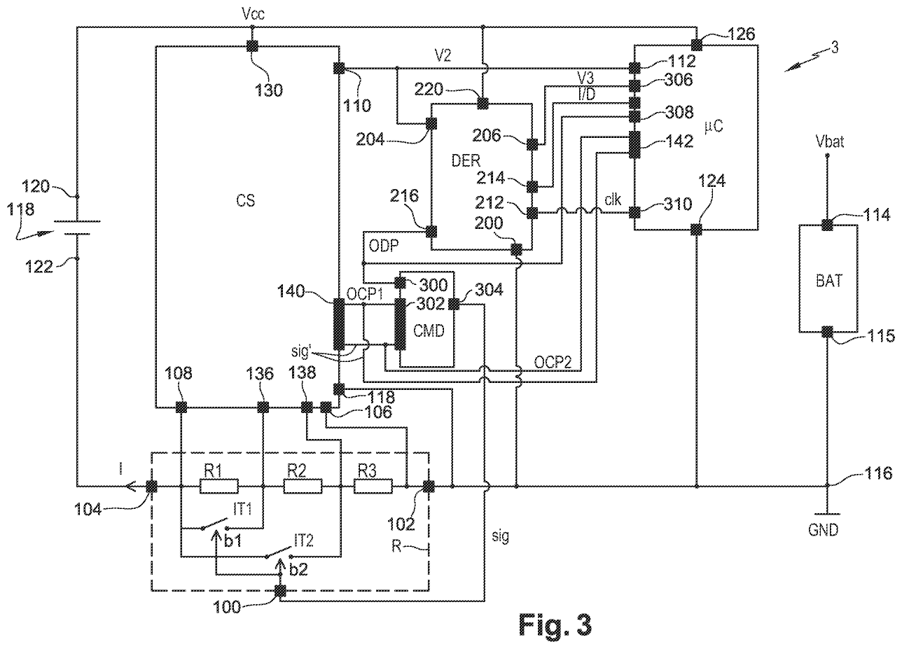

An embodiment of a circuit for measuring a derivative, for example a derivative of a voltage representative of a physical quantity, will now be described in relation with FIG. 2. Although this circuit may be used in a device 3 similar to device 1, as will be described in relation with FIG. 3, this measurement circuit enables to measure the derivative of any voltage representative of a physical quantity, for example temperature, this measured derivative not necessarily being used to implement protections against overcurrents.

FIG. 2 shows an example of embodiment of a circuit DER for measuring a derivative, for example a derivative of a voltage representative of a physical quantity according to the first aspect.

Circuit DER comprises three capacitive elements C1, C2, and C3, preferably identical. Each of elements C1, C2, and C3 has a first terminal connected to an input 200 of circuit DER, input 200 being configured to receive a reference potential GND.

Circuit DER further comprises an input 220 configured to receive a voltage for powering circuit DER and the circuits that it comprises.

Circuit DER further comprises first switches IT11, IT12, and IT13 coupling a second terminal of each of the respective elements C1, C2, and C3 to a node 202 of circuit DER.

For example, switch IT11 is connected between the second terminal of element C1 and node 202, switch IT12 is connected between the second terminal of capacitive element C2 and node 202, and switch IT13 is connected between the second terminal of element C3 and node 202.

Node 202 is configured to receive a voltage V1. Voltage V1 is determined by a voltage available on an input 204 of circuit DER, node 202 being coupled to input 204. In this example, circuit DER receives the voltage V2 described in relation with FIG. 1, or, in other words, a voltage V2 indicating the value of a current.

According to an embodiment, circuit DER comprises a circuit AMP coupling input 204 to node 202. For example, circuit AMP has an input connected to input 204 to receive voltage V2, and an output connected to node 202 to deliver voltage V1. Circuit AMP is a buffer circuit, that is, voltage V1 is equal to voltage V2. Circuit AMP enables to transfer charges draws of capacitive elements C1 to C3 onto the power supply of circuit DER rather than on voltage V2.

As a variant, node 202 is connected to input 204 and voltage V1 is equal to voltage V2.

Circuit DER is configured to measure, or calculate, the derivative of voltage V2, that is, to deliver a voltage V3 indicating a value, to within a multiplication factor, of the derivative of voltage V2.

For this purpose, circuit DER comprises a circuit DIFF. Circuit DIFF comprises two inputs 208 and 210 and one output configured to deliver voltage V3. The output of circuit DIFF is, for example, connected to output 206 of circuit DER. Circuit DIFF is configured so that voltage V3 indicates a value of a voltage difference between inputs 210 and 208, for example a value of the voltage on input 208 minus the voltage on input 210. As an example, circuit DIFF comprises an operational amplifier, for example assembled as a differential amplifier. As an example, although this is not illustrated in FIG. 2, circuit DIFF is connected to inputs 200 and 220 to be powered.

Further, circuit DER comprises second switches IT21, T22, IT23, IT24, IT25, IT26 coupling the second terminal of each of elements C1 to C3 to the inputs 208 and 210 of circuit DIFF. For example, each of elements C1 to C3 has its second terminal coupled to input 208 by one of the second switches and to input 210 another one of the second switches.

For example, switch IT21 is connected between the second terminal of element C1 and input 208 of circuit DIFF, switch IT22 is connected between the second terminal of element C1 and input 210 of circuit DIFF, switch IT23 is connected between the second terminal of element C2 and input 208 of circuit DIFF, switch IT24 is connected between the second terminal of element C2 and input 210 of circuit DIFF, switch IT25 is connected between the second terminal of element C3 and input 208 of circuit DIFF, and switch IT26 is connected between the second terminal of element C3 and input 210 of circuit DIFF.

Circuit DER comprises a circuit CTRL. Circuit CTRL is a circuit for controlling the first switches (IT11 to IT13) and the second switches (IT21 to IT26). As an example, although this is not illustrated in FIG. 2, circuit CTRL is connected to inputs 200 and 220 to be powered.

Circuit CTRL delivers the signals for controlling the first and second switches, for example on an output 222 of circuit CTRL. In FIG. 2, these control signals are not shown to avoid overloading FIG. 2. As an example, circuit CTRL delivers a control signal comprising a distinct control bit for each of the first and second switches.

Circuit CTRL is configured to implement successive operating cycles, each operating cycle corresponding to a succession of three periods of an internal clock signal of the device. Thus, each operating cycle comprises a first period of the internal clock signal, followed by a second period of the internal clock signal, itself followed by a third period of the internal clock signal. The following operating cycles do not overlap, or, in other words, none of the three periods of an operating cycle corresponds to one of the three periods of another operating cycle. The internal clock signal is determined by a clock signal clk. Circuit CTRL receives signal clk on an input 218 of circuit CTRL. Signal clk is received by circuit DER on an input 212 of circuit DER. For example, circuit CTRL has its input 218 connected to input 212.

According to an embodiment, the internal clock signal is identical to clock signal clk.

As a variant, the internal clock signal is obtained from signal clk, for example by a division of the frequency of signal clk.

Preferably, the signals for controlling the first and second switches are synchronized with the internal clock signal, for example with the rising and falling edges of the internal clock signal.

Circuit CTRL controls the first and second switches so that, at each first period of an operating cycle, voltage V1 is memorized on capacitive element C1, and, further, the inputs 208 and 210 of circuit DIFF receive the voltages of the respective elements C3 and C2.

More particularly, at each first period, circuit CTRL controls the first switches so that voltage V1 is memorized across capacitive element C1, and the second switches so that the second terminal of element C3 is coupled to input 208 of circuit DIFF and so that the second terminal of element C2 is coupled to input 210.

In other words, at each first period, circuit CTRL keeps switches IT12 and IT13 open and switches, during all or part of this first period, for example during the first part of this first period, switch IT11 to the on state. While switch IT11 is on, capacitive element C1 charges (or discharges) so that the voltage on the second terminal of element C1 becomes equal to voltage V1. When switch IT11 is switched back to the off state, this stores, on capacitive element C1, the voltage present thereacross, this voltage being equal to voltage V1 at the time of the switching to the off state of switch IT11. Further, at each first period, circuit CTRL switches, during all or part of the first period, for example during the first half of the first period, switches IT24 and IT25 to the on state while the other second switches are kept open. Thereby, the second terminal of element C3 is coupled to input 208 of circuit DIFF by switch IT25 in the on state, input 208 thus receiving the voltage across element C3, and the second terminal of element C2 is coupled to input 210 of circuit DIFF by switch IT24 in the on state, input 210 thus receiving the voltage across element C2.

The time window during which, for each first period, circuit CTRL couples with switches IT24 and IT25 elements C2 and C3 at respective inputs 210 and 208 may start during the third period preceding this first period. For example, this time window can start at half of the previous third period and end at half of the current first period.

Circuit CTRL controls the first and second switches so that, at each second period of an operating cycle, voltage V1 is memorized on capacitive element C2, and, further, inputs 208 and 210 of circuit DIFF receive the voltages of the respective elements C1 and C3.

More particularly, at each second period, circuit CTRL controls the first switches so that voltage V1 is memorized across capacitive element C2, and the second switches so that the second terminal of element C1 is coupled to the input 208 of circuit DIFF and that the second terminal of element C3 is coupled to input 210.

In other words, at each second period, circuit CTRL keeps switches IT11 and IT13 open and switches, during all or part of this second period, for example during the first half of this second period, switch IT12 to the on state. While switch IT12 is on, capacitive element C2 charges (or discharges) so that the voltage on the second terminal of element C2 becomes equal to voltage V1. When switch IT12 is switched back to the off state, this stores, on capacitive element C2, the voltage present thereacross, this voltage being equal to voltage V1 at the time of the switching to the off state of switch IT12. Further, at each second period, circuit CTRL switches, during all or part of the second period, for example during the first half of the second period, switches IT21 and IT26 to the on state while the other second switches are kept open. Thereby, the second terminal of element C1 is coupled to input 208 of circuit DIFF by switch IT25 in the on state, input 208 thus receiving the voltage across element C1, and the second terminal of element C3 is coupled to the input 210 of circuit DIFF by switch IT24 in the on state, input 210 thus receiving the voltage across element C3.

The time window during which, for each second period, circuit CTRL couples with switches IT21 and IT26 elements C1 and C3 at respective inputs 208 and 210 may start during the first period preceding this second period. For example, this time window may start at half of the first previous period and end at half of the current second period.

Circuit CTRL controls the first and second switches so that, at each third period of an operating cycle, voltage V3 is memorized on capacitive element C3, and, further, the inputs 208 and 210 of circuit DIFF receive the voltages of the respective elements C2 and C1.

More particularly, at each third period, circuit CTRL controls the first switches so that voltage V1 is memorized across capacitive element C3, and the second switches so that the second terminal of element C2 is coupled to input 208 of circuit DIFF and that the second terminal of element C1 is coupled to input 210.

In other words, at each third period, circuit CTRL keeps switches IT11 and IT12 open and switches, during all or part of this third period, for example during the first half of this third period, switch IT13 to the on state. While switch IT13 is on, capacitive element C3 charges (or discharges) so that the voltage on the second terminal of capacitive element C3 becomes equal to voltage V1. When switch IT13 is switched back to the off state, this stores, on capacitive element C3, the voltage present thereacross, this voltage being equal to the voltage V1 at the time of the switching to the off state of switch IT13. Further, at each third period, circuit CTRL switches, during all or part of the third period, for example during the first half of the third period, switches IT22 and IT23 to the on state while the other second switches are kept open. Thereby, the second terminal of element C2 is coupled to input 208 of circuit DIFF by switch IT23 in the on state, input 208 thus receiving the voltage across element C2, and the second terminal of element C1 is coupled to input 210 of circuit DIFF by switch IT22 in the on state, input 210 thus receiving the voltage across element C1.

The time window during which, for each third period, circuit CTRL couples with switches IT22 and IT23 elements C1 and C2 at respective inputs 210 and 208 may start during the second period preceding this third period. For example, this time window may start at half of the second previous period and end at half of the current third period.

According to an embodiment, each memorization of voltage V1 on a capacitive element C1, C2, C3 has a same duration, that is, the time window during which the corresponding first switch IT11, IT12, IT13 is on to implement this memorization has the same duration for each of the first, second, and third periods of the internal clock signal. This duration is, for example, shorter than or equal to the duration of a period of the internal clock signal, for example equal to a half-period of the internal clock signal.

Further, the duration Ton separating two successive memorizations, that is, the duration Ton separating the end of two successive memorizations, or, in other words, the duration Ton between the setting to the off state of switch IT11 and that of switch IT12, between the setting to the off state of switch IT12 and that of switch IT13, and between the setting to the off state of switch IT13 and that of switch IT11, is constant and is equal to one period of the internal clock signal.

To illustrates the operation of the above-described circuit DER, there are considered first and second successive operating cycles where:
voltage V1 is memorized on element C1 at a time to of the first period of the first cycle, whereby, at the end of the memorization, a voltage Vc1 across element C1 is equal to V1(t0) (voltage V1 at time t0);
voltage V1 is memorized on element C2 at a time to +Ton of the second period of the first cycle, whereby, at the end of the memorization, a voltage Vc2 across element C2 is equal to V1(t0+Ton);
voltage V1 is memorized on element C3 at a time to +2. Ton of the third period of the first cycle, whereby, at the end of the memorization, a voltage Vc3 across element C3 is equal to V1(t0+2·Ton);
voltage V1 is memorized on element C1 at a time to +3·Ton of the first period of the second cycle, whereby, at the end of the memorization, the voltage Vc1 across element C1 is equal to V1(t0+3·Ton);
voltage V1 is memorized on element C2 at a time to +4. Ton of the second period of the second cycle, whereby, at the end of the memorization, the voltage Vc2 across element C2 is equal to V1(t0+4·Ton); and
voltage V1 is memorized sur element C3 at a time to +5·Ton of the third period of the second cycle, whereby, at the end of the memorization, a voltage Vc3 across element C3 is equal to V1(t0+5·Ton).

Thus, in this example, during the first period of the second cycle, when elements C3 and C2 are coupled to the inputs of circuit DIFF, voltage V3 then is at a value determined by the difference between the voltage Vc3 across element C3, which is equal to V1(t0+2·Ton), and the voltage Vc2 across element C2, which is equal to V1(t0+Ton), voltage V3 then for example being equal to A·(V1(t0+2·Ton)−V1(t0+Ton)), and thus to A·(V1(t1+Ton)−V1(t1)), with t1 equal to t0+Ton and A a multiplication factor at least partly determined by the gain of circuit DIFF. Since voltage V1 is equal to voltage V2, this results in voltage V3 being equal to K·(V2(t1+Ton)−V2(t1))/Ton, and thus to K times the derivative of voltage V2 at time t1, with K equal to A. Ton.

Similarly, during the second period of the second cycle, when elements C1 and C3 are coupled to the inputs of circuit DIFF, voltage V3 then is at a value determined by the difference between the voltage Vc1 across element C3 that is equal to V1(t0+3·Ton) and the voltage Vc2 across element C2 that is equal to V1(t0+2·Ton), voltage V3 then for example being equal to A·(V1(t0+3·Ton)−V1(t0+2·Ton)), and thus to A·(V1(t2+Ton)−V1(t2)), with t2 equal to t0+2·Ton. As previously, voltage V3 is equal to K·(V2(t2+Ton)−V2(t2))/Ton, and thus to K times the derivative of voltage V2 at time t2.

Further, during the third period of the second operating cycle, when elements C1 and C2 are coupled to the inputs of circuit DIFF, voltage V3 then is at a value determined by the difference between the voltage Vc2 across element C2, which is equal to V1(t0+4·Ton), and the voltage Vc1 across element C3, which is equal to V1(t0+3·Ton), voltage V3 then for example being equal to A·(V1(t0+4·Ton)−V1(t0+3·Ton)), and thus to A·(V1(t3+Ton)−V1(t3)), with t3 equal to t0+3·Ton. As previously, voltage V3 is equal to K·(V2(t3+Ton)−V2(t3))/Ton, and thus to K times the derivative of voltage V2 at time t3.

The above circuit DER thus enables to deliver, at each period of the clock signal, a voltage V3 indicating the value of the derivative of voltage V2, the value of this voltage V3 being updated at each period of the internal clock signal. More particularly, the above circuit DER enables, at each period of the internal clock signal, to sample a value of voltage V1 on one of capacitive elements C1 to C3, and, within the same cycle, to deliver a value of the derivative of voltage V1 by using the voltage values V1 sampled on the two other capacitive elements. Thus, there is no cycle where no value of voltage V1 is sampled, and no cycle where no derivative value is provided.

Advantageously, circuit DER comprises no operational amplifier assembled as a differentiator, nor any analog-to-digital converter, nor any microprocessor.

According to an embodiment, circuit CTRL is configured to modify the frequency of the internal clock signal, and thus duration Ton. For example, when circuit DER is in a low-power operating mode, the frequency of the internal clock signal may be decreased to decrease the power consumption. As a complementary or alternative example, the frequency of the internal clock signal may be selected according to the application where circuit DER is implemented.

In practice, the value of capacitive elements C1 to C3 is determined by the frequency of the internal clock signal, so that the voltage across each of these elements does not vary, or then negligibly with respect to a targeted measurement accuracy, between a time when voltage V1 is memorized on this capacitive element and the times when this memorized voltage is delivered as an input of circuit DIFF. For example, the lower the frequency, the higher the capacitance value of elements C1 to C3.

However, this frequency may differ from one application to another where circuit DER is implemented, and it is then desirable not to size the capacitance values of the elements differently for each of these applications. This is in particular the case when circuit DER forms part of an integrated circuit chip.

Further, when circuit DER is an integrated circuit of an integrated circuit chip, it is desirable to have low capacitance values for elements C1 to C3, to limit the surface area occupied by circuit DER.

Thus, according to an embodiment, when circuit DER is an integrated circuit of an integrated circuit chip, a device comprising circuit DER further comprises, as illustrated in FIG. 2, capacitive elements C1′, C2′, C3′ connected in parallel with the respective capacitive elements C1, C2, and C3, and these elements C1′, C2′ and C3′ are arranged outside of the chip comprising circuit DER. Thereby, the capacitance value between switch IT11 and node 200, between switch IT12 and node 200, and between switch IT13 and node 200, may be increased and/or adjusted without modifying the capacitance value of elements C1 to C3. Preferably, elements C1′ to C3′ all have a same capacitance value.

As an example, element C1′ has a first terminal connected to input 200 of circuit DER, which is itself connected to the first terminal of element C1, and a second terminal connected to an input 224 of circuit DER, which is itself connected to the second terminal of element C1. As an example, element C2′ has a first terminal connected to input 200 of circuit DER, which is itself connected to the first terminal of element C2, and a second terminal connected to an input 226 of circuit DER, which is itself connected to the second terminal of element C2. As an example, element C3′ has a first terminal connected to input 200 of circuit DER, which is itself connected to the first terminal of element C3, and a second terminal connected to an input 228 of circuit DER, which is itself connected to the second terminal of element C3.

According to an embodiment, circuit CTRL is configured to control the gain of circuit DIFF, that is, the value of the above-described coefficient A.

According to an embodiment, as illustrated in FIG. 2, circuit DER comprises a capacitive element Cp connected between input 208 of circuit DIFF and input 200 of circuit DER, and a capacitive element Cm connected between input 210 of circuit DIFF and input 200 of circuit DER. These elements Cp and Cm have the same capacitance value. These elements Cp and Cm are smoothing (or low-pass filtering) capacitive elements. In other words, elements Cp and Cm enable to dim the effects of charge injections on the inputs of circuit DER during the switching of switches IT21 to IT26.

In an alternative embodiment, these elements Cp and Cm are however omitted.

According to an embodiment, it may be desirable for circuit DER to indicate when the derivative of voltage V2 exceeds a threshold Th, for example when circuit DER is intended for a use in a device of the type of the device 1 described in relation with FIG. 1. In this case, circuit DER comprises a circuit, or comparator, COMP2, for example an operational amplifier assembled, or configured, as a voltage comparator. Circuit COMP2 is configured to compare the output voltage V3 of circuit DIFF with a voltage Vref, voltage V3 indicating a value of the derivative of voltage V2 and voltage Vref indicating a value of threshold Th, and to deliver a signal ODP indicating the result of this comparison. The signal ODP indicating the result of the comparison of voltage V3 with voltage Vref, that is, of the comparison of the derivative of voltage V2 with threshold Vth, is delivered by circuit COMP2, for example by an output of circuit COMP2, to an output 216 of circuit DER.

As an example, circuit COMP2 has an input connected to the output of circuit DIFF to receive voltage V3, and an input configured to receive voltage Vref, and its output connected the output 216 of circuit DER.

As an example, voltage Vref is delivered by circuit CTRL.

As an example, when circuit CTRL is configured to modify the frequency of the internal clock signal (and thus duration Ton) and/or the gain of circuit DIFF, for a given threshold value Th, circuit CTRL is configured to adapt the value of voltage Vref to take into account variations of the frequency of the internal clock signal and/or of the gain of circuit DIFF.

According to an embodiment, it is desirable for circuit DER to also deliver an indication of the variation direction of the value of voltage V2, that is, of the sign of the derivative. In this case, circuit DER comprises a circuit, or comparator, COMP1, for example an operational amplifier assembled, or configured, as a voltage comparator. Circuit COMP1 is configured to compare with one another the voltages applied to the inputs of circuit DIFF, and to deliver a signal I/D indicating the result of this comparison. Signal I/D indicating the result of the comparison is delivered by circuit COMP1, for example by an output of circuit COMP1, to an output 214 of circuit DER.

As an example, circuit COMP1 has an input connected to the input 208 of circuit DIFF, an input connected to the input 210 of circuit DIFF, and its output connected to the output 214 of circuit DER.

As an example, although this is not illustrated in FIG. 2, an analog buffer circuit may be provided between each switch IT21 to IT26 and the corresponding input 210 and 208 of circuit DIFF. More particularly, an analog buffer circuit may be provided between a node of connection of switches IT21, IT23, and IT25 to one another and input 208 of circuit DIFF and/or an analog buffer circuit may be provided between a node of connection of switches IT22, IT24, and IT26 to one another and input 210 of circuit DIFF.

FIG. 3 shows, in the form of blocks, an example of embodiment of a current measurement device comprising a circuit DER for measuring a derivative such as described in relation with FIG. 2. Device 3 is similar to device 1 and only the differences between these two devices are detailed herein.

The device 3 of FIG. 3 comprises, like the device 1 of FIG. 1, circuit CS and controllable resistor R. However, in this example, the signal sig for controlling resistor R is not delivered by circuit CS. However, the output 140 of circuit CS delivers a signal sig′ determined by the results of the comparisons of the voltages across the inner resistors R1 to R3 of resistor R with corresponding thresholds.

More particularly, signal sig′ is, for example, identical to the signal sig described in relation with FIG. 1. Thus, signal sig′ is, for example formed of a signal OCP1 and of a signal OCP2. Signal OCP1 controls switch IT1, signal OCP2 controlling switch IT2.

As an example, device 3 further comprises, like device 1, power source 118.

As an example, device 3 comprises, like device 1, battery BAT.

As an example, device 3 comprises, like device 1, processing circuit μC, this circuit μC for example being a microprocessor. As an example, circuit μC receives signal sig′ on its input 142.

Device 3 further comprises circuit DER and a circuit for controlling switches CMD.

Circuit DER is, preferably, implemented on an integrated circuit chip.

Circuit DER has its input 220 that is for example connected to the terminal 120 of voltage source 118 to receive voltage Vcc, and its input 200 that is connected to node 116 to receive reference potential GND.

Circuit DER has its input 204 connected to the output 110 of circuit CS to receive voltage V2.

Circuit DER receives signal clk on its input 212, this signal clk being, for example, delivered by circuit μC, for example by an output 310 of circuit μC.

As an example, the voltage V3 indicating the value of the derivative of voltage V2, and thus the value of the derivative of current I, is delivered by circuit DER to circuit μC. For example, circuit μC has an input 306 coupled, preferably connected, to the output 206 of circuit DER to receive voltage V3.

Signal CMD is configured to deliver the signal sig for controlling resistor R, this signal sig here being different from that described in relation with FIG. 1. Indeed, in this embodiment, signal sig is at least partly determined by the comparison of voltage V3 with threshold Th that is implemented in circuit DER, and, thus, more widely, signal sig is at least partly determined by the voltage V3 of the output 206 of circuit DER.

In this embodiment, circuit DER comprises circuit COMP2 (not shown in FIG. 3) and output 216. The output 216 of circuit DER is coupled, preferably connected, to circuit CMD, for example to an input 300 of circuit CMD. As an example, signal ODP is also delivered to circuit μC, for example at an input 308 of circuit μC.

More particularly, circuit CMD also receives, from circuit CS, the signal sig′ indicating the set point value of resistor R according to the variation of current I therein, for example on an input 302 of circuit CMD.

Signal sig is then determined based on signal ODP and on signal sig′, that is, based on signal ODP and on signals OCP1 and OCP2 in this example. As an example, signal sig is a signal over a number of bits equal to the number of switches of resistor R, for example two bits b1 and b2 in this example, each bit of signal sig controlling a different switch of resistor R. For example, bit b1 controls switch IT1 and bit b2 controls switch IT2.

Circuit CMD thus not only receives signal sig′ indicating thereto which value resistor R should take in view of the current I flowing therethrough, but also the signal ODP indicating when the derivative of voltage V2 exceeds threshold Th.

Thus, circuit CMD delivers a resistor control signal sig that, for example, forces the resistor to a value smaller than that indicated by signal sig′ when the derivative of voltage V2 exceeds threshold Th, that is, when current I varies rapidly, which might result in a destruction of resistor R before signal sig indicates to circuit CMD that the value of resistor R be decreased.

For example, signal sig indicates, by its bit b1, that switch IT1 has to be switched to the on state if signal OCP1 indicates that this switch IT1 has to be switched to the on state and/or if signal ODP indicates that the derivative of voltage V2 has exceeded the threshold, signal sig further indicating, by its bit b2, that switch IT2 has to be switched to the on state if signal OCP2 indicates that this switch IT2 has to be switched to the on state and/or if signal ODP indicates that the derivative of voltage V2 has exceeded the threshold.

As an example, circuit DER comprises output 214 and circuit COMP1 (not shown in FIG. 3) that delivers signal I/D to this output 214. As an example, this signal I/D is delivered to circuit μC. For example, circuit μC has an input 312 coupled, preferably connected, to the output 214 of circuit DER.

Although in this example device 3 does not comprise capacitive elements C1′, C2′, and C3′, this may be the case in other examples, not illustrated.

In the above device 3, circuit DER and circuit CMD are shown as circuits external to circuit CS. However, in other examples, not illustrated, circuits CS, DER, and CMD may be implemented in a same general circuit, for example a circuit of an integrated circuit chip. In this case, the connection of circuits CMD, DER, and CS within this general circuit is similar to what has been previously described. Further, each input, respectively output, of circuits CMD, CS, and DER coupled or connected to an element external to this general circuit then also forms an input, respectively an output, of the general circuit, it being understood that when at least two of circuits CMD, DER, and CS have inputs, respectively outputs, coupled or connected to a same element external to the general circuit, the latter only comprises a single corresponding input, respectively output. As an example, referring again to the example of device 3 such as illustrated in FIG. 3, and considering that circuits CMD, DER, and CS form part of a same general circuit, this general circuit will have inputs corresponding to the inputs 106, 108, 136, 118, and 130 of circuit CS and to the input 212 of circuit DER, and outputs corresponding to the outputs 206, 214, 216 of circuit DER, to the output 304 of circuit CMD, and to the outputs 110 and 140 of circuit CS.

In the above-described example of device 3, resistor R comprises three resistors in series. However, those skilled in the art will be capable of adapting the description made hereabove to the case where resistor R only comprises two resistors in series, or, conversely, four resistors in series or more.

### Second Aspect

In the embodiments of the above-described first aspect, circuit DER comprises M capacitive elements, with M an integer equal to 3 in the first aspect. Circuit DER implements successive operating cycles, each comprising M successive periods of an internal clock signal, and, at each period of a cycle, circuit DER controls a memorization of an input voltage on one of the M capacitive elements and, further, implements a difference between a first voltage memorized on one of the M capacitive elements at a first time and a second voltage representative of the input voltage at a second time subsequent to the first time and separated from the first time by a constant duration, for example equal to a period of the internal clock.

More particularly, in the first aspect, that of the M capacitive elements having the memorization performed thereon is modified at each period of a given cycle and is different for each of the M periods of this cycle.

Further, in the first aspect, at each period of a given cycle, the first voltage is the voltage across one of the M capacitive elements other than that on which is performed the memorization for this period, and the second voltage representative of the input voltage is the voltage across one of the M capacitive elements other than that on which is performed the memorization for this period and other than that across which is available the first voltage for this period.

In the second aspect, as in the first aspect, circuit DER comprises M capacitive elements, with M a positive non-zero integer. Circuit DER implements successive operating cycles, each comprising M successive periods of an internal clock signal, and, at each period of a cycle, circuit DER controls a memorization of an input voltage on one of the M capacitive elements and, further, implements a difference between a first voltage memorized on one of the M capacitive elements at a first time and a second voltage representative of the input voltage at a second time subsequent to the first time and separated from the first time by a constant duration, for example equal to a period of the internal clock.

However, as compared with the first aspect, in the second aspect, M is equal to 2.

More particularly, in the second aspect, that of the M capacitive elements having the memorization performed thereon is modified at each period of a given cycle and is different for each of the M periods of this cycle.

Further, in the second aspect, at each period of a given cycle, the first voltage is the voltage across that of the M capacitive elements on which the input voltage has been memorized at this period, and the second voltage representative of the input voltage is the voltage across one of the M capacitive elements other than that on which is performed the memorization for this period.

Detailed embodiments of a derivative calculation circuit DER according to the second aspect will now be described.

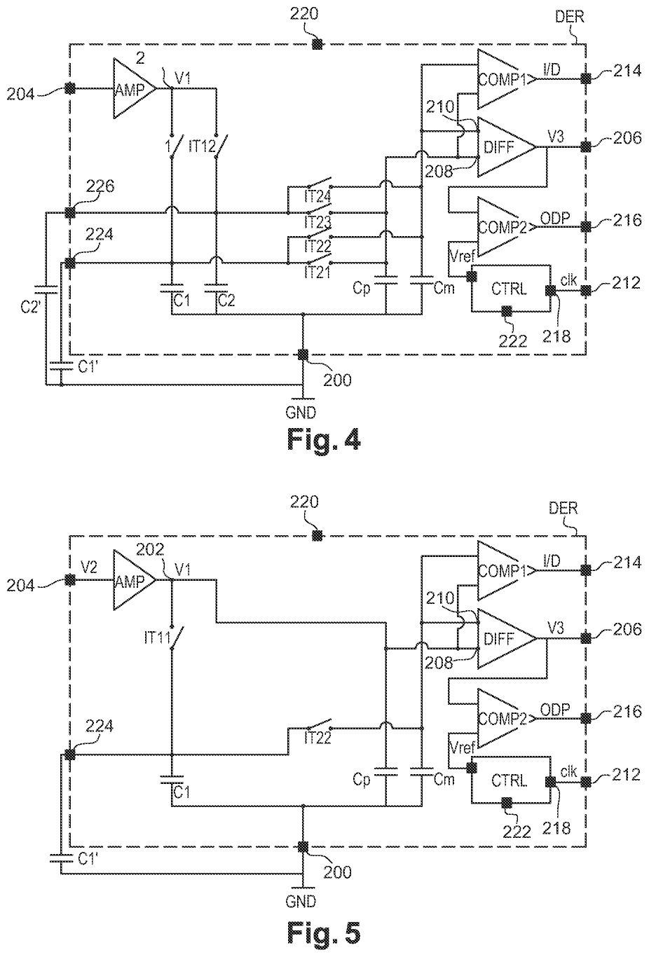

FIG. 4 illustrates an example of embodiment of circuit DER for measuring a derivative, for example a derivative of a voltage representative of a physical quantity, according to the second aspect.

The circuit DER according to the second aspect comprises many elements in common with the circuit DER according to the first aspect, and only the differences between these two circuits are here highlighted. Thus, unless indicated otherwise, all that has been described for the circuit DER according to the first aspect applies to the circuit DER according to the second aspect.

In particular, as compared with the circuit DER according to the first aspect, the circuit DER according to the second aspect only comprises M=2 capacitive elements for storing the voltage V1 representative of (or determined by) the voltage V2 for which circuit DER calculates the derivative. Thus, as compared with the circuit DER according to the first aspect, the circuit DER according to the second aspect does not comprise capacitive element C3.

The circuit DER according to the second aspect thus does not comprise either all the other elements of the circuit DER according to the first aspect that are linked to capacitive element C3. Thus, the circuit DER according to the second aspect does not comprise switches IT25 and IT26, switch IT13, and, in embodiments where capacitive elements C2′ and C1′ are connected in parallel with capacitive elements C2 and C1 respectively, capacitive element C3′ and input 228.

Further, in this second aspect, the circuit CTRL for controlling the first switches (IT11 and IT12) and the second switches (IT21 to IT24) is configured to implement successive operating cycles, each operating cycle corresponding to a succession of M=2 periods of the internal clock signal of device DER. Each operating cycle thus comprises a first period of the internal clock signal, followed by a second period of the internal clock signal, where the successive operating cycles do not overlap.

At each first period of an operating cycle, circuit CTRL controls the first and second switches so that voltage V1 is memorized on capacitive element C1, and, further, the inputs 208 and 210 of circuit DIFF receive the voltages of the respective elements C1 and C2.

More particularly, at each first period, circuit CTRL first controls the first switches so that voltage V1 is memorized across capacitive element C1, then controls the second switches so that the second terminal of element C1 is coupled to input 208 of circuit DIFF and that the second terminal of element C2 is coupled to input 210.

In other words, at each first period, circuit CTRL keeps switch IT12 open and switches, during all or part of this first period, for example during the first half of this first period, switch IT11 to the on state. While switch IT11 is on, capacitive element C1 charges (or discharges) so that the voltage on the second terminal of element C1 becomes equal to voltage V1. When switch IT11 is switched back to the off state, this stores, on capacitive element C1, the voltage present thereacross, this voltage being equal to voltage V1 at the time of the switching to the off state of switch IT11. Preferably, while switch IT11 is in the on state, switches IT22 to IT23 are kept open. Then, circuit CTRL switches, during all or part of the first period, for example during the second half of the first period, switches IT21 and IT24 to the on state while the other second switches IT22 and IT23 are kept open. Thereby, the second terminal of element C1 then is coupled to input 208 of circuit DIFF by switch IT21 in the on state and the second terminal of element C2 is coupled to input 210 of circuit DIFF by switch IT24 in the on state.

The time window during which, for each first period, circuit CTRL couples with switches IT21 and IT24 elements C1 and C2 at respective inputs 208 and 210 during this first period starts after voltage V1 has been memorized on capacitive element C1.

At each second period of an operating cycle, circuit CTRL controls the first and second switches so that voltage V1 is memorized on capacitive element C2, and, further, the inputs 208 and 210 of circuit DIFF receive the voltages of respective elements C2 and C1.

More particularly, at each second period, circuit CTRL first controls the first switches so that voltage V1 is memorized across capacitive element C2, then controls the second switches so that the second terminal of element C2 is coupled to the input 208 of circuit DIFF and that the second terminal of element C1 is coupled to input 210.

In other words, at each second period, circuit CTRL keeps switch IT11 open and switches, during all or part of this second period, for example during the first half of this second period, switch IT12 to the on state. While switch IT12 is on, capacitive element C2 charges (or discharges) to voltage V1. When switch IT12 is switched back to the off state, this stores voltage V1 on capacitive element C2. Preferably, while switch IT12 is in the on state, switches IT21 to IT24 are kept open. Then, circuit CTRL switches, during all or part of the second period, for example during the second half of the second period, switches IT23 and IT22 to the on state while the other second switches IT21 to IT24 are kept open. Thereby, the second terminal of element C2 is coupled to input 208 of circuit DIFF by switch IT23 in the on state and the second terminal of element C1 is coupled to input 210 of circuit DIFF by switch IT24 in the on state.

The time window during which, for each second period, circuit CTRL couples elements C2 and C1 at respective inputs 208 and 210 with switches IT22 and IT23 in the on state during this first period starts after voltage V1 has been memorized on capacitive element C2.

According to an embodiment, each memorization of the voltage V1 on a capacitive element C1, C2, has a same duration, that is, the time window during which the corresponding first switch IT11, IT12 is on has the same duration for each of the first and second periods of the internal clock signal. This duration is, for example, shorter than the duration of a period of the internal clock signal, for example equal to a half-period of the internal clock signal.

Further, the duration Ton separating two successive memorizations, for example the duration Ton between the setting to the off state of switch IT11 and that of switch IT12, and between the setting to the off state of switch IT12 and that of switch IT11, is constant and is equal to one period the internal clock signal.

To illustrate the operation of the circuit DER described hereabove in relation with the second aspect, there are considered a first and a second successive operating cycles in which:
voltage V1 is memorized on element C1 at a time to of the first period of the first cycle, whereby, at the end of the memorization, a voltage Vc1 across element C1 is equal to V1(t0);
voltage V1 is memorized on element C2 at a time to +Ton of the second period of the first cycle, whereby, at the end of the memorization, a voltage Vc2 across element C2 is equal to V1(t0+Ton);
voltage V1 is memorized on element C1 at a time to +2·Ton of the first period of the second cycle, whereby, at the end of the memorization, a voltage Vc1 across element C1 is equal to V1(t0+2·Ton); and
voltage V1 is memorized on element C2 at a time to +3·Ton of the second period of the second cycle, whereby, at the end of the memorization, the voltage Vc2 across element C2 is equal to V1(t0+3·Ton).

Thus, in this example, during the second period of the first cycle, when elements C1 and C2 are coupled to the inputs of circuit DIFF after the memorization of voltage V1 across element C2, voltage V3 then is at a value determined by the difference between the voltage Vc2 across element C1, which is equal to V1(t0+Ton), and the voltage Vc1 across element C1, which is equal to V1(t0), voltage V3 then for example being equal to A·(V1(t0+Ton)−V1(t0)). Since voltage V1 is, in this example, equal to voltage V2, this results in voltage V3 being equal to K·(V2(t0+Ton)−V2(t0))/Ton, and thus to K times the derivative of voltage V2 at time to, with K equal to A·Ton.

Similarly, during the first period of the second cycle, when elements C1 and C2 are coupled to the inputs of circuit DIFF after the memorization of the voltage V1 across element C1, voltage V3 then is at a value determined by the difference between the voltage Vc1 across element C1, which is equal to V1(t0+2·Ton), and the voltage Vc2 across element C2, which is equal to V1(t0+Ton), voltage V3 then for example being equal to A·(V1(t0+2·Ton)−V1(t0+Ton)), and thus to A·(V1(t1+Ton)−V1(t1)), with t1 equal to t0+Ton. As previously, voltage V3 is equal to K·(V2(t2+Ton)−V2(t2))/Ton, and thus to K times the derivative of voltage V2 at time t1.

Those skilled in the art will be capable of deducing the operation of circuit DER during the next internal clock periods based on the operation described hereabove as an example.

The above circuit DER thus enables to deliver, at each period of the clock signal, a voltage V3 indicating the value of the derivative of voltage V2, the value of this voltage V3 being updated at each period of the internal clock signal. Thus, there is no cycle where no value of voltage V1 is sampled, nor any cycle where no derivative value is provided.

Advantageously, circuit DER comprises no operational amplifier assembled as a differentiator, nor any analog-to-digital converter and microprocessor.

As compared with the circuit DER according to the first aspect, the circuit DER according to the second aspect is simpler to implement. However, while the circuit DER according to the first aspect can deliver a voltage V3 that, for each calculated derivative value, can remain stable for duration Ton until voltage V3 is updated, in the circuit DER according to the first aspect, this duration during which each calculated derivative value can remain stable is equal to duration Ton minus the duration of the phase of memorization of voltage V1 on one or the other of elements C1 and C2. Those skilled in the art will be capable of providing for the circuits using voltage V3 to read or use the current value of voltage V3 at a time when voltage V3 has a stable value.

### Third Aspect

In this third aspect, as for the first and second previously-described aspects, circuit DER comprises M capacitive elements, with a M positive and non-zero integer. Circuit DER implements successive operating cycles, each comprising M successive periods of an internal clock signal, and, at each period of a cycle, circuit DER controls a memorization of an input voltage on one of the M capacitive elements and, further, implements a difference between a first voltage memorized on one of the M capacitive elements at a first time and a second voltage representative of the input voltage at a second time subsequent to the first time and separated from the first time by a constant duration, for example equal to one period of the internal clock.

However, as compared with the first aspect where M is equal to 3 and with the second aspect where M is equal to 2, in the third aspect, M is equal to 1.

More particularly, in the third aspect, that of the M capacitive elements having the memorization performed thereon is thus the same at each period of each cycle. Further, at each period of each cycle, the first voltage is the voltage across the capacitive element on which the input voltage has been memorized at this period, and the second voltage representative of the input voltage is directly the input voltage.

Detailed embodiments of a derivative calculation circuit DER according to the third aspect will now be described.

FIG. 5 illustrates an example of embodiment of circuit DER for measuring a derivative, for example a derivative of a voltage representative of a physical quantity, according to the third aspect.

The circuit DER according to the third aspect comprises many elements in common with the circuit DER according to the first aspect, and only the differences between these two circuits are here highlighted. Thus, unless indicated otherwise, all that has been described for the circuit DER according to the first aspect applies to the circuit DER according to the third aspect.

In particular, as compared with the circuit DER according to the first aspect, the circuit DER according to the third aspect only comprises M=1 capacitive element to store the voltage V1 representative of (or determined by) the voltage V2 for which circuit DER calculates the derivative. Thus, as compared with the circuit DER according to the first aspect, the circuit DER according to the third aspect does not comprise capacitive element C3 and does not comprise capacitive element C2 either.

The circuit DER according to the third aspect thus does not comprise either all the other elements of the circuit DER according to the first aspect that are linked to capacitive element C3 and to capacitive element C2. Thus, the circuit DER according to the third aspect does not comprise switches IT23 to IT26, switches IT13 and IT12, and, in embodiments where a capacitive element C1′ is connected in parallel with capacitive element C1, capacitive elements C3′ and C2′ and inputs 228 and 226.

In this third aspect, the switch IT21 coupling capacitive element C1 to input 208 of circuit DIFF is omitted. Further, the node 202 on which voltage V1 is available is coupled, for example by an analog buffer circuit, or connected, to input 208 of circuit DIFF.

Further, in this third aspect, the circuit CTRL for controlling the first and second switches (IT11, IT22) is configured to implement successive operating cycles, each operating cycle corresponding to a succession of M=1 period of the internal clock signal of device DER. In other words, each operating cycle only comprises one period of the internal clock signal, called first period hereafter.

At each first period of an operating cycle, or, in other words, at each period of internal clock signal, circuit CTRL controls the first and second switches so that voltage V1 is memorized on capacitive element C1, and, further, the inputs 208 and 210 of circuit DIFF receive voltage V1 and the voltage memorized across capacitive element C1.

More particularly, at each first period, circuit CTRL first controls first switch IT11 so that voltage V1 is memorized across capacitive element C1, then controls second switch IT22 so that the second terminal of element C1 is coupled to input 210 of circuit DIFF and that node 202 is coupled to input 208 of circuit DIFF.

In other words, at each first period, circuit CTRL switches, during all or part of this first period, for example during the first half of this first period, switch IT11 to the on state. While switch IT11 is on, capacitive element C1 charges (or discharges) to voltage V1. When switch IT11 is switched back to the off state, this stores, on capacitive element C1, voltage V1 at the time of the switching to the off state of switch IT11. Then, circuit CTRL switches, during all or part of the first period, for example during the second half of the first period, switch IT22 to the on state. Thereby, the second terminal of element C1 is then coupled to input 210 of circuit DIFF by switch IT21 in the on state and voltage V1 is delivered to input 208 of circuit DIFF.

The time window during which, for each first period, circuit CTRL couples, with switch IT22, element C1 at input 210 starts after voltage V1 has been memorized on this same capacitive element C1.

According to an embodiment, each memorization of voltage V1 on capacitive element C1 has a same duration, that is, the time window during which first switch IT11 is on has the same duration for each first period of the internal clock signal. This duration is, for example, shorter than the duration of a period of the internal clock signal, for example equal to half a period of the internal clock signal.

Further, the duration Ton separating two successive memorizations, for example the duration Ton between the setting to the off state of switch IT11 during the first period of a given operating cycle and that of switch IT11 during the first period of the next operating cycle, is constant and equal to one period of the internal clock signal.

To illustrate the operation of the circuit DER described hereabove in relation with the third aspect, there are considered a first and a second successive operating cycles in which:
voltage V1 is memorized on element C1 at a time to of the first period of the first cycle, whereby, at the end of the memorization, a voltage Vc1 across element C1 is equal to V1(t0); and
voltage V1 is memorized on element C1 at a time to +Ton of the first period of the second cycle, whereby, at the end of the memorization, the voltage Vc1 across element C1 is equal to V1(t0+Ton).

Thus, in this example, during the first period of each cycle, when element C1 is coupled to input 210 of circuit DIFF after the memorization of voltage V1 across element C1, voltage V3 then is at a value determined by the difference between the voltage Vc1 across element C1, which is equal to V1(t0), and voltage V1, which is equal to V1(t), with t a time of this first period subsequent to time to. For example, when time to corresponds to the end of the first half of the first period, and voltage V3 is read at a time t1 corresponding to the end of the second half of the first period, and Ton corresponds to the duration of a period of the internal clock signal, the voltage V3 at the end of the first period (time t1) then is for example equal to A·(V1(t0+(Ton/2))−V1(t0)). Since voltage V1 is, in this example, equal to voltage V2, this results in voltage V3, at time t1, being equal to K·(V2(t0+(Ton/2))−V2(t0))/(Ton/2), and thus to K times the derivative of voltage V2 at time to, with K equal to A·Ton/2.

The above circuit DER thus enables to deliver, at each period of the clock signal, a voltage V3 indicating the value of the derivative of voltage V2, the value of this voltage V3 being updated at each period of the internal clock signal. Thus, there is no cycle where no value of voltage V1 is sampled, nor any cycle where no derivative value is provided.

There has been described hereabove an example where half a period of the internal clock signal separates, at each cycle, the time to of end of memorization of voltage V1 on C1 from the time t1 when voltage V3 is read, whereby voltage V3(t1) at time t1 is equal to K times the derivative of voltage V2, with K equal to A·Ton/2. Those skilled in the art may select another duration value, for example Ton/4, separating time to from time t1, whereby voltage V3(t1) will be equal to K times the derivative of voltage V2 with K different from A·Ton/2, for example equal to A·Ton/4.

Advantageously, circuit DER comprises no operational amplifier assembled as a differentiator, nor any analog-to-digital converter and microprocessor.

As compared with the circuit DER according to the first and second aspects, the circuit DER according to the third aspect is simpler to implement. However, while the circuit DER according to the first aspect can deliver a voltage V3 that, for each calculated derivative value, can remain stable for duration Ton until the voltage is updated, and the circuit DER according to the second aspect can deliver a voltage V3 that, for each calculated derivative value, can remain stable for duration Ton minus the duration of the phase of memorization of voltage V1 on one or the other of elements C1 and C2, in the circuit DER according to the third aspect, the value of voltage V3 will have to be read at a predefined time t1, for example at the end of each period of the internal signal, to know the factor K between voltage V3 and the value of the derivative of voltage V1 at this time t1. Those skilled in the art will be capable of providing for the circuits using voltage V3 to read or use the current value of voltage V3 at time t1 when voltage V3 is effectively equal to K times the derivative of voltage V1, for example by providing to store the value of voltage V3 at this time t1.

### Fourth Aspect

In the embodiments previously described in relation with any of the first, second, and third aspect, the value or voltage V3 representative of the calculated value of the derivative of input voltage V2 is compared with a threshold TH determined by voltage Vref. An alarm ODP is triggered as soon as the value of the calculated derivative exceeds this threshold, that is, as soon as voltage V3 exceeds threshold Vref.

In these embodiments, threshold TH and the corresponding voltage Vref are constant. Thus, when voltage V1 has a low value representing a low value of the corresponding physical quantity (for example a current through a resistor), and this voltage V1 abruptly increases, voltage V3 may rise above threshold Vref and trigger an alarm ODP while, in practice, voltage V1 may, after its abrupt increase, reach a stable value below a value threshold of voltage V1 for which it is not necessary to provide an action (for example a decrease of a resistance value). In this case, an alarm ODP is triggered while this is not necessary. Conversely, when voltage V1 has a high value representing a high value of the corresponding physical quantity (for example a current through a resistor), and this value is very close to the value threshold of voltage V1 for which it is necessary to provide an action (for example a decrease of a resistance value), if voltage V1 increases slowly to reach this value threshold, voltage V3 remains below Vref, and triggers no alarm ODP ahead of the time when voltage V1 exceeds its value threshold. In this case, no alarm ODP is triggered while this would have been desirable.

Thus, in the fourth aspect, a calculated derivative value, or a quantity representative of this calculated value, for example voltage V3, is compared with a threshold, for example Vref, and an alarm is triggered at least partly based on the result of this comparison. However, in the fourth aspect, the threshold is dependent on the current value of the quantity having the derivative calculated thereon. In other words, the value of the threshold is adapted at least based on the current value of the voltage, for example V1, having the derivative calculated thereon.

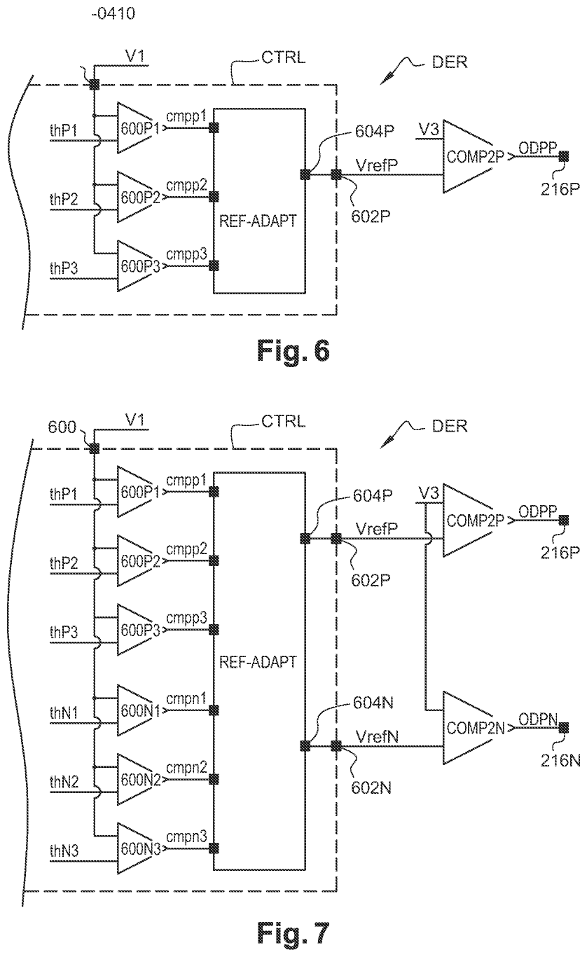

FIG. 6 illustrates an example of embodiment of circuit DER for measuring a derivative, for example a derivative of a voltage V1 representative of a physical quantity, according to the fourth aspect.

In FIG. 6, circuit DER and circuit CTRL are partially shown.

In this example, voltage V1 is positive and increasing with the physical quantity, for example a current through a resistor, that it represents.

In this example, the derivative of voltage V3 is compared with a positive threshold designated hereafter by reference THP.

In this example, the voltage representative of the threshold THP with which voltage V3 is compared to provide an alarm signal is designated with reference VrefP and is positive, the binary alarm signal is designated with reference ODPP, the comparator comparing voltage V3 with voltage Vref to deliver the alarm signal is designated with reference COMP2P, and the output 216 delivering alarm signal ODPP is designated with reference 216P instead of the respective references Vref, ODP, COMP2, and 216 used in the above-described FIGS. 2 to 5.

In this embodiment, circuit CTRL comprises an input 600 configured to receive voltage V1. Further, circuit CTRL is configured to decrease, preferably discretely, the value of threshold THP, and thus that of voltage VrefP, when voltage V1 increases, and to increase threshold value THP, and thus that of voltage VrefP, when voltage V1 decreases.

In this embodiment, circuit CTRL further comprises an output 602P configured to deliver threshold voltage VrefP to the comparator COMP2P of circuit DER, the latter also receiving voltage V3 representative of the derivative of voltage V1. As previously described, comparator COMP2P is configured to compare voltage V3 with voltage VrefP, and to deliver a binary signal ODPP representative of the result de this comparison.

In this embodiment, signal ODPP is delivered at the output 216P of circuit DER.

According to an embodiment, circuit CTRL comprises Q comparators 600Pi (600P1, 600P2, 600P3 in FIG. 6), with Q a positive integer greater than or equal to 1, preferably greater than or equal to 2, for example equal to 3 in FIG. 6, and i an integer index ranging from 1 to Q.

Each comparator 600Pi is configured to compare voltage V1 with a corresponding positive threshold thPi (thP1, thP2, thP3 in FIG. 6), thresholds thPi being different from one another. Each comparator 600Pi delivers a binary signal cmppi (cmpp1, cmpp2, cmpp3 in FIG. 6) representative of the result of this comparison.

Circuit CTRL further comprises a circuit REF-ADAPT configured to deliver voltage VrefP, for example on an output 604P of circuit CTRL, and to adapt the value of this voltage VrefP according to signals cmppi, that is, according to the current value of voltage V1. As an example, circuit REF-ADAPT receives signals cmppi on corresponding inputs of circuit REF-ADAPT.

For example, in the case where the value of thresholds thPi increases with index i and where voltage V1 increases with the physical quantity that it represents, circuit REF-ADAPT is configured to deliver voltage VrefP at a maximum value when voltage V1 is smaller than threshold thP1, at a first value smaller than the maximum value when voltage V1 is between thresholds thP1 and thP2, at a second value smaller than the first value when voltage V1 is between thresholds thP2 and thP3, and at a minimum value smaller than the second value when voltage V1 is greater than threshold thP3.

As an example, although this is not illustrated in FIG. 6, circuit REF-ADAPT comprises a resistive dividing bridge having an intermediate node configured to deliver voltage VrefP, and a value of a resistive element of this dividing bridge is controlled by signals cmppi to obtain the above-described operation. The implementation of such a circuit is within the abilities of those skilled in the art based on the functional indications given hereabove. Further, those skilled in the art will be capable of providing other implementations of circuit REF-ADAPT having the above-described operation.

FIG. 7 illustrates another example of embodiment of circuit DER for measuring a derivative, for example a derivative of a voltage V1 representative of a physical quantity, according to the fourth aspect.

In FIG. 7, as in FIG. 6, circuit DER and circuit CTRL are partially shown. The circuit DER described in relation with FIG. 7 comprises many elements in common with the circuit DER described in relation with FIG. 6, and only the differences between these two circuits DER are here highlighted.

In this example, voltage V1 increases with the physical quantity, for example a current in a resistor, that it represents. Further, in this example, voltage V1 takes positive values and negative values. For example, this may be the case when voltage V1 represents the value of a current through a resistor and this current can flow in one direction and in another in the resistor.

In the same way as an alarm ODPP indicates when the derivative of voltage V1 exceeds a positive threshold THP, it is then desirable for an alarm ODPN to indicate when the derivative of voltage V1 exceeds a negative threshold THN, that is, decreases below this negative threshold THN. Thereby, when voltage V1 is negative and decreases, if the value of the derivative of voltage V1 decreases below threshold THN, an alarm ODPN is triggered, and a corresponding action can be implemented in anticipated fashion, without waiting for voltage V1 to decrease below a negative value threshold.

Thus, in this example, symmetrically to what has been previously described in relation with FIG. 6, it is provided for the derivative of voltage V1 to be compared with a negative threshold THN, in addition to being compared with a positive threshold THP. Circuit DER is then configured to deliver an additional binary alarm signal ODPN indicating when the value of the derivative of voltage V1 is smaller than threshold THN.

In this example, the voltage representative of threshold THN with which voltage V3 is compared to provide alarm signal ODPN is designated with reference VrefN and is negative, circuit DER then comprising an additional comparator COMP2N comparing voltage V3 with voltage VrefN and delivering binary alarm signal ODPN. Further, circuit DER comprises an additional output 216N configured to deliver signal ODPN.

In this embodiment, circuit CTRL is further configured to decrease, preferably discretely, the absolute value of threshold THN, and thus that of voltage VrefP, when voltage V1 is negative and decreases, or, in other words, when voltage V1 is negative and increases in absolute value. Further, circuit CTRL is configured to increase the absolute value of threshold THN, and thus that of voltage VrefN when voltage V1 is negative and increases, or, in other words, when voltage V1 is negative and decreases in absolute value.

In this embodiment, circuit CTRL further comprises an output 602N configured to deliver threshold voltage VrefN to the comparator COMP2N of circuit DER, the latter also receiving the voltage V3 representative of the derivative of voltage V1. Comparator COMP2N is configured to compare voltage V3 with voltage VrefN, and to deliver the binary signal ODPN representative of the result of this comparison.

In this embodiment, signal ODPN is delivered at output 216N of circuit DER.

According to an embodiment, circuit CTRL comprises, in addition to the Q comparators 600Pi delivering signals cmppi, K comparators 600Nj (600N1, 600N2, 600N3 in FIG. 7), with K a positive integer greater than or equal to 1, preferably greater than or equal to 2, for example equal to 3 in FIG. 7, and j an integer index ranging from 1 to K. Preferably, numbers K and Q are equal although, in other examples, numbers K and Q may be different.

Each comparator 600Nj is configured to compare voltage V1 with a corresponding negative threshold thNj (thN1, thN2, thN3 in FIG. 7), thresholds thNj being different from one another. Each comparator 600Nj delivers a binary signal cmpnj (cmpn1, cmpn2, cmpn3 in FIG. 7) representative of the result of this comparison.

Circuit REF-ADAPT is configured to deliver voltage VrefN, for example on an output 604N of circuit CTRL, in addition to the voltage VrefP that it delivers, for example, at output 604P. Circuit REF-ADAPT is further configured to adapt the value of this voltage VrefN according to signals cmpnj, that is, according to the current value of voltage V1. As an example, circuit REF-ADAPT receives signals cmpni on corresponding inputs of circuit REF-ADAPT.

For example, in the case where the absolute value of thresholds thNj increases with index j and where voltage V1 increases with the physical quantity that it represents, circuit REF-ADAPT is configured to deliver negative voltage VrefN at an absolute maximum value when negative voltage V1 is, in absolute value, smaller than the absolute value of negative threshold thP1, at a first value smaller, in absolute value, than the absolute value of the maximum value when voltage V1 is between thresholds thP1 and thP2, at a second value smaller, in absolute value, than the absolute value of the first value when voltage V1 is between thresholds thP2 and thP3, and at a minimum absolute value smaller, in absolute value, than the absolute value of the second value when voltage V1 is, in absolute value, greater than the absolute value of threshold thP3. In other words, circuit REF-ADAPT is configured to deliver negative voltage VrefN at a maximum negative value when negative voltage V1 is between a zero value and negative threshold thP1, at a first negative value closer to a zero value than the maximum negative value when voltage V1 is between thresholds thP1 and thP2, at a second negative value closer to a zero value than the first negative value when voltage V1 is between thresholds thP2 and thP3, and at a minimum negative value closer to a zero value than the second negative value when voltage V1 is more negative than threshold thP3.

As an example, although this is not illustrated in FIG. 7, circuit REF-ADAPT comprises, for example in addition to the resistive bridge delivering voltage VrefP, a resistive dividing bridge having an intermediate node configured to deliver voltage VrefN, a value of a resistive element of this dividing bridge being controlled by signals cmpnj to obtain the above-described operation. The implementation of such a circuit is within the abilities of those skilled in the art based on the functional indications given hereabove. Further, those skilled in the art will be capable of providing other implementations of circuit REF-ADAPT having the above-described operation.

Although there has been described, in relation with FIG. 6, an example of embodiment where voltage V1 is positive and the derivative of voltage V1 is compared with a positive variable threshold THP, and, in relation with FIG. 7, an example of embodiment where voltage V1 takes positive and negative values and its derivative is compared with positive variable threshold THP and with a negative variable threshold THN, in an alternative embodiment, voltage V1 is negative and its derivative is only compared with negative variable threshold THN. The implementation of such a variant is within the abilities of those skilled in the art based on the description of circuit DER made hereabove in relation with FIGS. 6 and 7.

For example, in such a variant, as compared with the circuit DER described in relation with FIG. 7, comparator COMP2P and output 216P are omitted, and further, circuit CTRL does not deliver voltage VrefP and does not comprise output 602P. Circuit CTRL is thus not configured to adapt the value of voltage VrefP according to the current value of voltage V1, or, in other words, circuit REF-ADAPT does not deliver voltage VrefP, does not comprise output 604P, and is not configured to adapt the value of voltage VrefP according to the current value of voltage V1. For example, circuit CTRL does not comprise comparators 600Pi.

In the examples of embodiments and variants described hereabove in relation with FIGS. 6 and 7:
when voltage V1 is positive and increases, the value of positive threshold THP, and thus that of positive voltage VrefP, decreases each time voltage V1 becomes greater than one of thresholds thPi, and, conversely, when voltage V1 is positive and decreases, the value of threshold THP, and thus that of voltage VrefP, increases each time voltage V1 becomes smaller than one of thresholds thPi; and/or
when voltage V1 is negative and increases in absolute value, the value of negative threshold THN, and thus that of negative voltage VrefN, decreases in absolute value each time the absolute value of voltage V1 becomes greater than the absolute value at one of thresholds thNj, and, conversely, when voltage V1 is negative and decreases in absolute value, the value of negative threshold THN, and thus that of negative voltage VrefN, increases in absolute value each time the absolute value of voltage V1 becomes smaller than the absolute value at one of thresholds thNj.

In other words, in these embodiments and variants, the absolute value of threshold THP (voltage VrefP) and/or the absolute value of threshold THN (voltage VrefN) are each adapted, preferably discretely, to increase and to decrease only based on the value of voltage V1.

In other embodiments and variants, it is desirable that:
when voltage V1 is positive:
if voltage V1 increases, the value of positive threshold THP, and thus that of positive voltage VrefP, decreases each time voltage V1 becomes greater than one of thresholds thPi, and
if voltage V1 decreases, the value of threshold THP, and thus that of voltage VrefP, increases each time voltage V1 becomes smaller than one of thresholds thPi if the derivative of voltage V1, that is, voltage V3, is negative, and is not modified if the derivative of voltage V1 is positive; and/or
when voltage V1 negative:
if voltage V1 increases in absolute value, the value of negative threshold THN, and thus that of negative voltage VrefN, decreases in absolute value each time the absolute value of voltage V1 becomes greater than the absolute value of one of thresholds thNj, and if voltage V1 decreases in absolute value, the value of threshold THN, and thus that of voltage VrefN, increases in absolute value each time the absolute value of voltage V1 becomes smaller than one of thresholds thNi if the derivative of voltage V1, that is, voltage V3, is positive, and is not modified if the derivative of voltage V1 is negative.

In these embodiments and variants, the current value of threshold THP and/or the current value of threshold THN are each modified, in absolute value:
downwards only based on the current value of voltage V1, and
upwards based not only on the current value of voltage V1 but also taking into account the polarity of the derivative of voltage V1, that is, the polarity of voltage V3.

This enables to take into account the delay between an increase of the absolute value of voltage V1, and the corresponding variation of the value of the derivative, that is, of the value of voltage V3, during the comparison of voltage V3 with one and/or the other of voltages VrefP and VrefN, and, in particular, due to the fact that voltage V1 may, in absolute value, decrease during this delay.

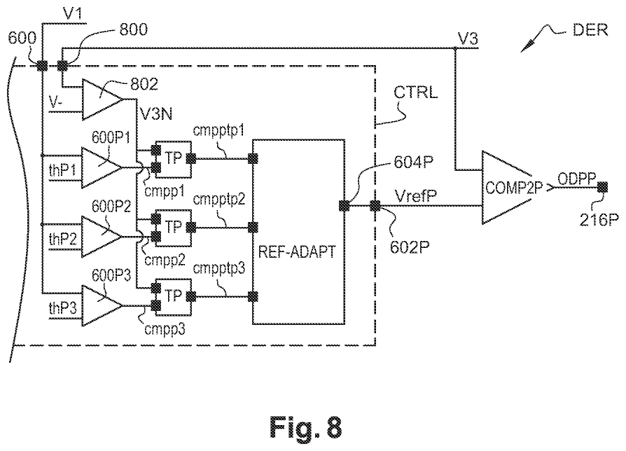

FIG. 8 illustrates an example of such an embodiment of circuit DER. More particularly, FIG. 8 shows an adaptation of the embodiment of circuit DER described in relation with FIG. 6, in the case where the upward modification of threshold THP, and thus of voltage VrefP, according to the value of voltage V1, is conditioned by the polarity of the derivative, that is, by the polarity of voltage V3. For example, in FIG. 8, the upward modification of threshold THP, and thus of voltage VrefP, is only effective if the derivative of voltage V1, that is, voltage V3, is negative.

Thus, the circuit DER of FIG. 8 comprises many elements in common with that of FIG. 6, and only the differences between these two circuits are here highlighted. Further, as in FIG. 6, in FIG. 8 circuit DER and its circuit CTRL are partially shown.

In FIG. 8, circuit CTRL is configured to implement the above-described operation where voltage VrefP is adapted downwards when voltage V1 increases, and is adapted upwards, for example when voltage V1 decreases, according to the value of voltage V1 and to the polarity of voltage V3.

As an example, circuit CTRL comprises an additional input 800 configured to receive voltage V3. Circuit DER also comprises an additional comparator 802 configured to compare voltage V3 with a zero or slightly negative voltage V−, and deliver a binary signal V3N indicating the result of this comparison, that is, the polarity (positive or negative) of voltage V3.

For example, voltage V− is in a range of values from 0 V to −100 mV. Voltage V− is for example equal to −50 mV.

Further, in the example of circuit DER of FIG. 8, signals cmppi are not directly delivered to circuit REF-ADAPT, but are each delivered to a corresponding circuit TP. Each circuit TP further receives signal V3N and is configured to deliver a binary signal cmpptpi (cmpptp1, cmpptp2, cmpptp3 in FIG. 8) determined by the signals cmppi and V3N received by this circuit TP.

More particularly, each circuit TP is, for example, configured to:
switch its signal cmpptpi from a first binary state of this signal to a second binary state of this signal when its signal cmppi switches from a first binary state of this signal indicating that voltage V1 is smaller than threshold thPi to a second binary state of this signal indicating that voltage V1 is greater than threshold thPi;
   switch its signal cmpptpi from its second binary state to its first binary state when its signal cmppi is in its first binary state and, simultaneously, signal V3N indicates that voltage V3 is negative; and
   keep signal cmpptpi in its current state otherwise.

In this example of circuit CTRL, circuit REF-ADAPT modifies the value of voltage VrefP at each modification of the binary state of one of signals cmpptpi. For example, circuit REF-ADAPT receives signals cmpptpi instead of signals cmppi. For example, circuit REF-ADAPT decreases the value of voltage VrefP each time a signal cmpptpi switches from its first binary state to its second binary state, and increases the value of voltage VrefP each time a signal cmpptpi switches from its second binary state to its first binary state.

As an example, those skilled in the art may implement each circuit TP based on an RS-type flip-flop having a set input S only controlled based on the signal cmppi received by this circuit TP, a reset input R controlled based on a combinatorial combination of the signals cmppi and V3N received by this circuit TP, and an output Q delivering or determining the signal cmpptpi delivered by this circuit TP.

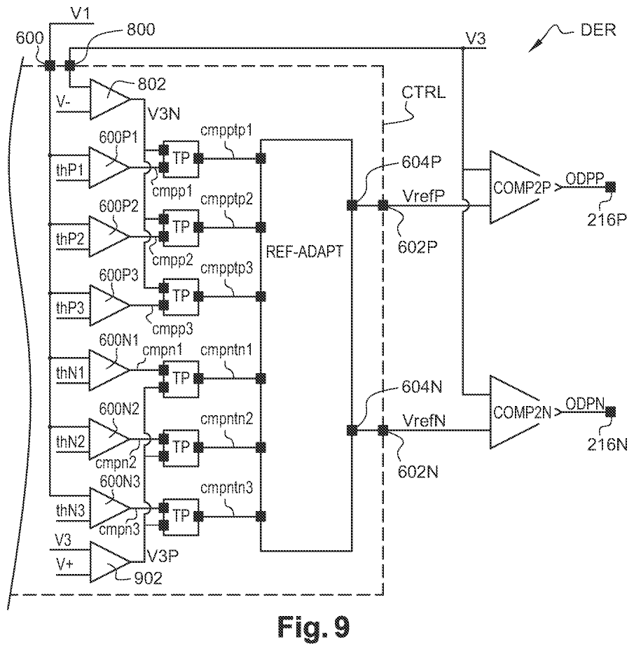

FIG. 9 illustrates another example of such an embodiment of circuit DER. More particularly, FIG. 9 shows an adaptation of the embodiment of the circuit DER described in relation with FIG. 7, in the case where:
the upward modification of threshold THP, and thus of voltage VrefP, according to the value of voltage V1 is conditioned by the polarity of the derivative, that is, by the polarity of voltage V3, for example by conditioning each upward modification of voltage VrefP to the fact that the derivative of voltage V1, that is, voltage V3, is negative; and
the upward modification of the absolute value of threshold THN, and thus of the absolute value of voltage VrefN, according to the value of voltage V1 is conditioned by the polarity of the derivative, that is, by the polarity of voltage V3, for example by conditioning each upward modification of the absolute value of voltage VrefN to the fact that the derivative of voltage V1, that is, voltage V3, is positive.

Thus, the circuit DER of FIG. 9 comprises many elements in common with that of FIG. 7, and only the differences between these two circuits are here highlighted. Further, as in FIG. 7, in FIG. 9 circuit DER and its circuit CTRL are partially shown.

In FIG. 9, circuit CTRL is configured to implement the above-described operation where the downward modifications of the absolute value of each of voltages VrefP and VrefN only depend on the current value of voltage V1, and the upward modifications of the absolute value of each of voltages VrefP and VrefN depend not only on the current value of voltage V1, but are further conditioned by the polarity of voltage V3, or, in other words, these upward modifications depend on the current value of voltage V1 and on the polarity of voltage V3.

As an example, for this purpose, circuit CTRL comprises an additional comparator 902 configured to compare voltage V3 with a zero or slightly positive voltage V+, and to deliver a binary signal V3P indicating the result of this comparison, that is, the polarity (positive or negative) of voltage V3.

For example, voltage V+ is in a range of values from 0 V to 100 mV. Voltage V+ is for example equal to +50 mV.

Further, in the example of circuit DER of FIG. 8, signals cmpnj are not directly delivered to circuit REF-ADAPT, but are each delivered to a corresponding circuit TN. Each circuit TN further receives signal V3P and is configured to deliver a binary signal cmpntnj (cmpntn1, cmpntn2, cmpntn3 in FIG. 9) determined by the signals cmpnj and V2N received by this circuit TN.

More particularly, each circuit TN is, for example, configured to:
switch its signal cmpntnj from a first binary state of this signal to a second binary state of this signal when its signal cmpnj switches from a first binary state of this signal indicating that voltage V1 is negative and smaller in absolute value than the absolute value of threshold thNj, to a second binary state of this signal indicating that voltage V1 is negative and greater in absolute value than the absolute value of threshold thNi;
switch its signal cmpntnj from its second binary state to its first binary state when its signal cmpnj is at its first binary state and, simultaneously, signal V3P indicates that voltage V3 is positive; and
keep signal cmpntnj in its current state otherwise.

In this example of circuit CTRL, circuit REF-ADAPT modifies the value of voltage VrefN at each modification of the binary state of one of signals cmpntnij. For example, circuit REF-ADAPT receives signals cmpntnj instead of signals cmpnj. For example, circuit REF-ADAPT decreases, in absolute value, the value of voltage VrefN each time a signal cmpntnj switches from its first binary state to its second binary state, and increases, in absolute value, the value of voltage VrefN each time signal cmpntnj switches from its second binary state to its first binary state.

As an example, those skilled in the art may implement each circuit TN based on an RS-type flip-flop having a set input S only controlled based on the signal cmpnj received by this circuit TN, a reset input R controlled based on a combinatorial combination of the signals cmpnj and V3P received by this circuit TN, and an output Q delivering or determining the signal cmpntnj delivered by this circuit TP.

In still other embodiments, rather than delivering binary alarm signals ODPP and ODPN, it is desirable for circuit DER to be configured to:
deliver a binary alarm signal ODPPP in a first binary state indicating that the derivative of voltage V1 is greater than threshold VrefP, that is, indicating that the current value of voltage V3 is greater than voltage VrefP, only if voltage V1 is positive, and, more particularly, only if the last value of voltage V1 used to calculate this current value of voltage V3 is positive, and
deliver a binary alarm signal ODPNN in a first binary state indicating that the derivative of voltage V1 is smaller than threshold VrefN, that is, indicating than the current value of voltage V3 is smaller than voltage VrefN, only if voltage V1 is negative, and, more particularly, only if the last value of voltage V1 used to calculate this current value of voltage V3 is negative.

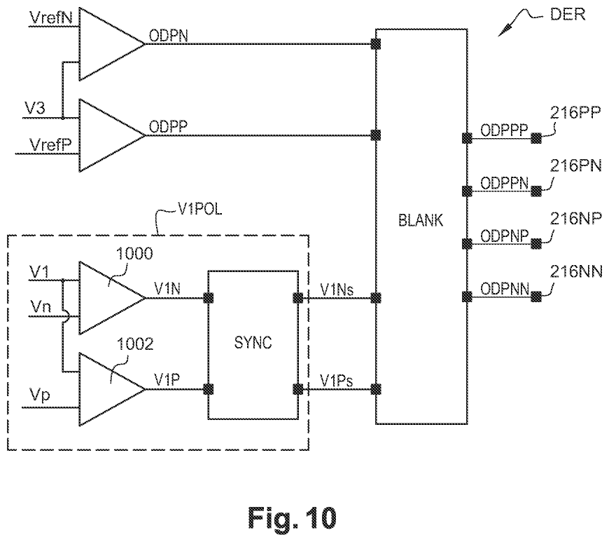

FIG. 10 illustrates an example of such an embodiment of a circuit DER, circuit DER being partially shown in FIG. 10.

As an example, although this is not illustrated in FIG. 10, circuit DER further comprises a circuit CTRL such as described in relation with FIG. 7 or with FIG. 9.

In this example of embodiment, circuit DER comprises, in addition to comparators COMP2N and COMP2P, a circuit V1POL configured to indicate by at least one binary signal, for example by means of two binary signals V1Ns and V1Ps, the polarity of the last value of voltage V1 used to calculate the current value of voltage V3. In other words, circuit V1POL is configured to synchronize values of the voltage V1 with corresponding values of voltage V3, and to indicate, by at least one binary signal, the polarity of each value of voltage V1 resynchronized with a corresponding value of voltage V3.

For example, signal V1Ps indicates by its binary state whether the last value of voltage V1 used to calculate the derivative of voltage V1 is positive or not. For example, a first binary state of signal V1Ps indicates that the last value of voltage V1 used to calculate the derivative of voltage V1 is positive and a second binary state of signal V1Ps indicates that the last value of voltage V1 used to calculate the derivative of voltage V1 is negative or zero. Symmetrically, for example, signal V1Ns indicates by its binary state whether the last value of voltage V1 used to calculate the derivative of voltage V1 is negative or not. For example, a first binary state of signal V1Ns indicates that the last value of voltage V1 used to calculate the derivative of voltage V1 is negative and a second binary state of signal V1Ns indicates that the last value of voltage V1 used to calculate the derivative of voltage V1 is positive or zero.

For example, when circuit DER is implemented according to the first aspect or according to the second aspect, circuit V1POL indicates the polarity of the last value of voltage V1 memorized and used to calculate the current value of voltage V3.

As a more specific example, in the second aspect or the third aspect, the current value of voltage V3 is calculated based on a difference between two voltages memorized on two corresponding capacitive elements among the M capacitive elements, and circuit V1POL indicates the polarity of that of the two voltages that has been memorized last.

For example, when circuit DER is implemented according to the third aspect, circuit V1POL indicates that the polarity of voltage V1 at the time when the value of voltage V3 indicates a correct derivative value of voltage V1. As an example, it is here considered that voltage V3 is updated only at times when the current value of voltage V1 used to calculate voltage V3 corresponds to a correct derivative value.

As a more specific example, in the third aspect, when the memorizations of voltage V1 on capacitive element C1 are implemented at each falling, respectively rising, edge of the internal clock of circuit DER and the value of voltage V3 is read at each rising, respectively falling, edge of this internal clock so that factor K has a known value, the value of voltage V3 is then updated at each rising, respectively falling, edge of the internal clock, and is held at its current value between two successive updates.

As an example, circuit V1POL comprises a comparator 1000 configured to compare voltage V1 with a zero or slightly negative voltage Vn. For example, voltage Vn is in a range of values from 0 V to −20 mV. Voltage Vn is for example equal to −5 mV. Comparator 1000 is configured to deliver a binary signal VIN indicating whether voltage V1 is greater than voltage Vn or smaller than voltage Vn. Still in this example, circuit V1POL comprises a comparator 1002 configured to compare voltage V1 with a zero or slightly positive voltage Vp. For example, voltage Vp is in a range of values from 0 V to 20 mV. Voltage Vp is for example equal to 5 mV. Comparator 1002 is configured to deliver a binary signal V1P indicating whether voltage V1 is greater than voltage Vp or smaller than voltage Vp. In addition to comparators 1000 and 1002, circuit V1POL comprises, in this example, a circuit SYNC configured to store the state of signals V1N and V1P on the respective binary signals V1Ns and V1Ps, each time that, in the first and second aspects, voltage V1 is memorized on one of the M capacitive elements, or, in the third aspect, voltage V3 has a value for which the value of coefficient K is known, or, in other words, the value of voltage V3 corresponds to a correct value of the derivative of voltage V1.

As an example, not illustrated, the two comparators 1000 and 1002 may be replaced with a single comparator comparing voltage V1 with a zero voltage.

As another example not illustrated, circuit SYNC is configured to store the value of voltage V1 each time that, in the first and second aspects, voltage V1 is memorized on one of the M capacitive elements, or, in the third aspect, voltage V3 has a value for which the value of coefficient K is known, or, in other words, the value of voltage V3 corresponds to a correct value of the derivative of voltage V1. In this other example, the memorized value of the voltage available at the output of circuit SYNC is then compared with the two voltages Vn and Vp to obtain signals V1Ns and V1Ps, or with a zero voltage to obtain a single output signal of circuit V1POL.

Circuit DER further comprises a combinational circuit BLANK configured to deliver alarm signals OPPP and ODPN based on signals ODPP and ODPN as well as on the output signal(s) of circuit V1POL. For example, circuit BLANK receives signals ODPP and ODPN. For example, circuit BLANK receives the output signal(s) of circuit V1POL, for example signals V1NS and VIPS.

More particularly, circuit BLANK is configured to:
deliver binary signal ODPPP in a first binary state indicating that the derivative of voltage V1 is greater than threshold VrefP if signal ODPP indicates that voltage V3 is greater than threshold VrefP while the last value of voltage V1 used to calculate this current value of voltage V3 is positive, and in a second binary state otherwise and
deliver alarm binary signal ODPNN in a first binary state indicating that the derivative of voltage V1 is smaller than threshold VrefN if signal ODPN indicates that voltage V3 is smaller than threshold VrefN while the last value of voltage V1 used to calculate this current value of voltage V3 is negative, and in a second binary state otherwise.

For example, circuit BLANK is configured to:
deliver binary signal ODPPP in a first binary state indicating that the derivative of voltage V1 is greater than threshold VrefP if signal ODPP indicates that voltage V3 is greater than threshold VrefP while signal V1Ps is in its first binary state, and to deliver signal ODPPP in its second binary state otherwise; and
deliver binary alarm signal ODPNN in a first binary state indicating that the derivative of voltage V1 is smaller than threshold VrefN if signal ODPN indicates that voltage V3 is smaller than threshold VrefN while signal V1Ns is in its first binary state, and to deliver signal ODPPN in its second binary state otherwise.

Signals ODPPP and ODPNN are delivered at outputs 216PP and 216NN of circuit DER, which then comprises none of outputs 216, 216N, and 216P, the latter being replaced with outputs 216PP and 216NN.

Optionally, based on signals ODPP and ODPN and on the output signal(s) of circuit SYNC, circuit BLANK is further configured to:
deliver a binary signal ODPPN in a first binary state indicating that the derivative of voltage V1 is greater than threshold VrefP if signal ODPP indicates that voltage V3 is greater than threshold VrefP while the last value of voltage V1 used to calculate this current value of voltage V3 is negative, and in a second binary state otherwise and/or
deliver the binary alarm signal ODPNN in a first binary state indicating that the derivative of voltage V1 is smaller than threshold VrefN if signal ODPN indicates that voltage V3 is smaller than threshold VrefN while the last value of voltage V1 used to calculate this current value of voltage V3 is negative, and in a second binary state otherwise.

Signals ODPPN and ODPPN are, for example, delivered at respective outputs 216PN and 216PN of circuit DER.

### Additional Aspects

In the circuits DER according to the first, second, and third aspects described hereabove, M is equal respectively to 3, 2, and 1. Although this results in an increase of the complexity of circuit DER, those skilled in the art may provide, based on the functional description given hereabove, additional fifth aspects where M is an integer greater than 3.

Further, although there has been described an embodiment of a device 3 where circuit DER is implemented according to the first aspect with M that is equal to 3, those skilled in the art will be capable of adapting the description of device 3 to the case of a circuit DER where M is equal to 1, 2, or more than 3.

More generally, those skilled in the art will be capable of implementing the device 3 having circuit DER implemented therein according to any of the first, second, third, and fifth aspects, combined or not with the fourth aspect. In particular, those skilled in the art will be capable of modifying circuit CMD according to whether circuit DER delivers signal ODP, signal ODPP, signal ODPN, the two signals ODPN and ODPP, or at least the two signals ODPPPP and ODPNN among signals ODPPP, ODPPN, ODPNP, and ODPNN.

The embodiments of the fourth aspect have been described as depending on any of the first, second, third, and fifth aspects. However, this fourth aspect may be implemented with other circuits for calculating a derivative of a quantity. Indeed, the comparison of the calculated derivative value with a threshold adapted according to the current value of the quantity having the derivative calculated thereon to trigger an alarm based on the result of this comparison does not require for the derivative calculation to be based on any of the first, second, third, and fifth aspects, and may be implemented by those skilled in the art, based on the functional indications given hereabove, with a derivative calculation based on the use of an ADC and/or of a microcontroller.

Further, those skilled in the art will understand that the dividing of circuit DER into a plurality of circuits is only done for illustration purposes, and that, in the previously-described circuits DER, a plurality of circuits may be gathered in a single circuit and/or a circuit may be divided into a plurality of circuits, provided for the functionalities of circuit DER to be kept.

Various embodiments and variants have been described. Those skilled in the art will understand that certain features of these various embodiments and variants may be combined, and other variants will occur to those skilled in the art. In particular, as already previously indicated, the use of circuit DER is not limited to an implementation in device 3, and, more widely, to the measurement of the derivative of a voltage V3 representative of the value of a current I.

Finally, the practical implementation of the described embodiments and variants is within the abilities of those skilled in the art based on the functional indications given hereabove.

What is claimed is:

1. A derivative measurement circuit, comprising:
M capacitive elements, wherein M is an integer greater than or equal to 1, each having a first terminal connected to a first input of the measurement circuit configured to receive a reference potential;
M first switches coupling a second terminal of each of the M capacitive elements to a first node configured to receive a first voltage determined by a voltage at a second input of the measurement circuit coupled with the first node;
a first circuit configured to deliver, at a first output of the measurement circuit, a second voltage indicating a value of a voltage difference between first and second inputs of the first circuit;
second switches coupling the second terminal of each of the M capacitive elements to the inputs of the first circuit; and
a control circuit configured to:
receive a first clock signal available at a third input of the measurement circuit;
implement successive cycles corresponding each to a succession of M periods of a second clock signal determined by the first clock signal; and
control the switches such that, at each period of each cycle:
the first voltage is memorized on one of the M capacitive elements; and
the first input of the first circuit receives a voltage memorized at a first instant on one of the M capacitive elements and the second input of the first circuit receives a voltage representative of the first voltage at a second instant different from the first instant.

2. The derivative measurement circuit according to claim 1, wherein:
M is equal to 1;
the first input of the first circuit is coupled to the first node; and
the control circuit is configured to control the switches such that, at each period of each cycle, the second input of the first circuit receives the voltage memorized on the capacitive element at this period.

3. The derivative measurement circuit according to claim 1, wherein:
M is equal to 2; and
the control circuit is configured to control the switches such that, at each cycle:
that of the M capacitive elements on which the first voltage is memorized is different at each period of the cycle, and
at each period of the cycle, the second input of the first circuit receives a voltage across the terminals of one of the M capacitive elements other than the one on which the memorization is done at this cycle, and the first input of the first circuit receives a voltage across the other of the M capacitive elements.

4. The derivative measurement circuit according to claim 1, wherein:
M is equal to 3; and
the control circuit is configured to control the switches such that, at each cycle:
that of the M capacitive elements on which the first voltage is memorized is different at each period of the cycle, and
at each period of the cycle, the first input of the first circuit receives a voltage across the terminals of one of the M capacitive elements other than the one on which the memorization is done at this cycle, and the second input of the first circuit receives a voltage across of another of the M capacitive elements other than the one on which the memorization is done at this period.

5. The derivative measurement circuit according to claim 1, wherein:
M is equal to 3;
each cycle corresponds to a succession of first, second and third periods of the second clock signal; and
the control circuit is configured to control the switches such that:
at each first period, the first voltage is memorized on a first element and the first and second inputs of the first circuit receive voltages of third and second elements, respectively,
at each second period, the first voltage is memorized on the second element and the first and second inputs of the first circuit receive voltages of the first and third elements, respectively, and
at each third period, the first voltage is memorized on the third element and the first and second inputs of the first circuit receive voltages of the second and first elements, respectively.

6. The derivative measurement circuit according to claim 5, wherein the first switches comprise a first first switch coupling the second terminal of the first element with the first node, a second first switch coupling the second terminal of the second element with the first node, and a third first switch coupling the second terminal of the third element with the first node.

7. The derivative measurement circuit according to claim 5, wherein the control circuit is configured to:
at each first period, keep open the second and third first switches and switch the first first switch to an ON state;
at each second period, keep open the third and first first switches and switch the second first switch to the ON state; and
at each third period, keep open the second and first first switches and switch the third first switch to the ON state.

8. The derivative measurement circuit according to claim 5, wherein each memorization of the first voltage on the respective capacitive element has a same duration, for example less than or equal to one period of the second clock signal, preferably equal to half a period of the second clock signal.

9. The derivative measurement circuit according to claim 5, wherein the second switches comprise:
first and second second switches coupling the second terminal of the first element respectively with the first and second inputs of the first circuit;
third and fourth second switches coupling the second terminal of the second element respectively with the first and second inputs of the first circuit; and
fifth and sixth second switches coupling the second terminal of the third element respectively with the first and second inputs of the first circuit.

10. The derivative measurement circuit according to claim 9, wherein the control circuit is configured to:
at each first period, switch the fifth and fourth second switches to an ON state and keep open the other second switches;
at each second period, switch the first and sixth second switches to the ON state and keep open the other second switches; and
at each third period, switch the third and second second switches to the ON state and keep open the other second switches.

11. The derivative measurement circuit according to claim 1, wherein the measurement circuit further comprises a first smoothing capacitive element connected between the first input of the first circuit and the first input of the measurement circuit and a second smoothing capacitive element connected between the second input of the first circuit and the first input of the measurement circuit.

12. The derivative measurement circuit according to claim 1, wherein the measurement circuit further comprises a second circuit coupling the second input of the measurement circuit with the first node, wherein the second circuit is a buffer circuit.

13. The derivative measurement circuit according to claim 1, wherein the measurement circuit further comprises:
a first comparator configured to compare the second voltage with a positive threshold voltage provided by the control circuit, and to provide a first binary signal indicating if the second voltage is greater than the positive threshold voltage; and/or
a second comparator configured to compare the second voltage with a negative threshold voltage provided by the control circuit, and to provide a second binary signal indicating if the second voltage is lower than the positive threshold voltage.

14. The derivative measurement circuit according to claim 13, wherein:
the measurement circuit comprises the first comparator; and
the control circuit is configured to adapt a value of the positive threshold voltage as a function of a value of the first voltage.

15. The derivative measurement circuit according to claim 14, wherein the control circuit is configured to decrease the value of the positive threshold voltage when the first voltage is positive and increases.

16. The derivative measurement circuit according to claim 13, wherein:
the measurement circuit comprises the second comparator; and
the control circuit is configured to adapt a value of the negative threshold voltage as a function of a value of the first voltage.

17. The derivative measurement circuit according to claim 16, wherein the control circuit is configured to decrease an absolute value of the negative threshold voltage when the first voltage is negative and decreases.

18. A derivative measurement circuit, comprising:
M capacitive elements, wherein M is an integer greater than or equal to 1, each having a first terminal connected to a first input of the measurement circuit configured to receive a reference potential;
M first switches coupling a second terminal of each of the M capacitive elements to a first node configured to receive a first voltage determined by a voltage at a second input of the measurement circuit coupled with the first node;
a first circuit configured to deliver, at a first output of the measurement circuit, a second voltage indicating a value of a voltage difference between first and second inputs of the first circuit;
second switches coupling the second terminal of each of the M capacitive elements to the inputs of the first circuit;
a control circuit configured to:
receive a first clock signal available at a third input of the measurement circuit;
implement successive cycles corresponding each to a succession of M periods of a second clock signal determined by the first clock signal; and
control the switches such that, at each period of each cycle:
the first voltage is memorized on one of the M capacitive elements; and
the first input of the first circuit receives a voltage memorized at a first instant on one of the M capacitive elements and the second input of the first circuit receives a voltage representative of the first voltage at a second instant different from the first instant;
a first comparator configured to compare the second voltage with a positive threshold voltage provided by the control circuit, and to provide a first binary signal indicating if the second voltage is greater than the positive threshold voltage; and
a second comparator configured to compare the second voltage with a negative threshold voltage provided by the control circuit, and to provide a second binary signal indicating if the second voltage is lower than the positive threshold voltage.

19. The derivative measurement circuit according to claim 18, wherein the control circuit is configured to:
adapt a value of the positive threshold voltage as a function of a value of the first voltage; and
adapt a value of the negative threshold voltage as a function of a value of the first voltage.

20. A derivative measurement circuit, comprising:
M capacitive elements, wherein M is an integer greater than or equal to 1, each having a first terminal connected to a first input of the measurement circuit configured to receive a reference potential;
M first switches coupling a second terminal of each of the M capacitive elements to a first node configured to receive a first voltage determined by a voltage at a second input of the measurement circuit coupled with the first node;
a first circuit configured to deliver, at a first output of the measurement circuit, a second voltage indicating a value of a voltage difference between first and second inputs of the first circuit;
second switches coupling the second terminal of each of the M capacitive elements to the inputs of the first circuit;
a control circuit configured to:
receive a first clock signal available at a third input of the measurement circuit;
implement successive cycles corresponding each to a succession of M periods of a second clock signal determined by the first clock signal; and
control the switches such that, at each period of each cycle:
the first voltage is memorized on one of the M capacitive elements; and
the first input of the first circuit receives a voltage memorized at a first instant on one of the M capacitive elements and the second input of the first circuit receives a voltage representative of the first voltage at a second instant different from the first instant;
a first smoothing capacitive element connected between the first input of the first circuit and the first input of the measurement circuit and a second smoothing capacitive element connected between the second input of the first circuit and the first input of the measurement circuit; and
a second circuit coupling the second input of the measurement circuit with the first node, wherein the second circuit is a buffer circuit.
